(19) United States
(12) Patent Application Publication
(10) Pub. No.: US 2011/0058685 A1
(43) Pub. Date: Mar. 10, 2011

(54) METHOD OF SEPARATING SOUND SIGNAL

(75) Inventors: Shigeki Sagayama, Tokyo (JP); Nobutaka Ono, Tokyo (JP); Hirokazu Kameoka, Tokyo (JP); Kenichi Miyamoto, Tokyo (JP); Jonathan Le Roux, Tokyo (JP)

(73) Assignee: THE UNIVERSITY OF TOKYO, Tokyo (JP)

(21) Appl. No.: 12/920,299

(22) PCT Filed: Aug. 27, 2008
(86) PCT No.: PCT/JP2008/065287

§ 371 Date: Nov. 30, 2010

(30) Foreign Application Priority Data
Mar. 5, 2008 (JP) 2008-054826

(51) Int. Cl. H03G 5/00

(52) U.S. Cl. 381/98

(57) ABSTRACT

The present invention obtains a separated signal from an audio signal based on the anisotropy of smoothness of spectral elements in the time-frequency domain. A spectrogram of the audio signal is assumed to be a sum of a plurality of sub-spectrograms, and smoothness of spectral elements of each sub-spectrogram in the time-frequency domain has directionality on the time-frequency plane. The method comprises obtaining a distribution coefficient for distributing spectral elements of said audio signal in the time-frequency domain to at least one sub-spectrogram based on the directionality of the smoothness of each sub-spectrogram on the time-frequency plane, and separating at least one sub-spectrogram from said spectral elements of said audio signal using said distribution coefficient.

### TECHNICAL FIELD

The present invention relates to a method of separating an acoustic (sound) signal, typically a polyphonic acoustic signal. In the specification, the invention will be explained based on the separation of percussive component from music signal as a typical example, but application of the present invention is not limited to the separation of percussive component from the music signal. The present invention can be applied to the separation of industrial sound generated from machinery or device.

### BACKGROUND OF THE INVENTION

In processing of music signal such as music information retrieval and automatic music transcription, it is necessary to extract and recognize various information including pitch, harmony, rhythm pattern, tempo and the like from the music signal. Such attempt is still difficult task though the related studies have been developed in recent years. The music signal often comprises two different components: a harmonic component relating to melody and harmony, and a percussive component relating to rhythm and drum part. The two components are different signals having completely different characteristics. These two signals are mixed in the music signal which results in difficulty in analyzing the music signal. Indeed, it is not easy to separate harmonic/percussive components from a monaural acoustic signal and conventionally, such separation was attempted with the help of information regarding scores or music instruments involved. If such separation is conducted properly, it can be applied in various fields including pre-processing of polyphonic music signal having non-harmonic component such as percussion and noise, and modification of music such as emphasizing of percussion part and percussion pattern modification.

Several studies have been known for separating and extracting percussion (non-harmonic component) from a polyphonic music signal.

Non-patent document 1 (Development of Drum Equalizer System INTER:D, Using Drum Sound Identification Method for Real-World Music Signals, Kazuyoshi Yoshii, Masataka Goto, Hiroshi Okuno, FIT2004.) relates to frame-wise musical source identification by iterative estimation and deletion of particular sound by using template for an instrument to be deleted.

Non-patent document 2 (Selective Amplifier of Periodic and Non-periodic Components in Concurrent Audio Signals with Spectral Control Envelopes, Hirokazu Kameoka, Masataka Goto, Shigeki Sagayama” IPSJ SIG Technical Reports 2006-MUS-65, pp 77-84.) relates to frame-wise separation method of harmonic/non-harmonic components without using scores and employs iteration estimation.

According to Non-patent document 3 (M. Helen, T. Virtanen, “Separation of Drums from Polyphonic Music Using Non-negative Matrix Factorization and Support Vector Machine,” In proc, 13th EUSIPCO, 2005.), frequency characteristics of harmonic sound and percussion sound are pre-trained by trained data and these sounds are separated frame-wisely by matching with trained characteristics.

An object of the present invention is to separate an acoustic signal based on the anisotropy of smoothness of spectral elements in the time-frequency domain in contrast with the conventional frame-wise analyzing methods. One of more specific objects of the present invention is to separate harmonic component and non-harmonic component such as percussive component from music signal without using information regarding scores and music instruments.

### SUMMARY OF THE INVENTION

The present invention relates to a method of separating an acoustic signal wherein a spectrogram of the acoustic signal is assumed to be a sum of a plurality of sub-spectrograms, and smoothness of spectral elements of each sub-spectrogram in a time-frequency domain has directionality on a time-frequency plane. The method comprises obtaining a distribution coefficient for distributing spectral elements of said acoustic signal in the time-frequency domain to at least one sub-spectrogram based on the directionality of the smoothness of each sub-spectrogram on the time-frequency plane, and separating at least one sub-spectrogram from the spectral elements of the acoustic signal using the distribution coefficient.

The present invention focuses on the difference of smoothness direction of spectral elements of spectrogram of acoustic signal in the time-frequency domain. The present invention uses not only changes in frequency characteristic but also temporal changes of spectral elements. According to the present invention, it is assumed that the acoustic signal is the sum of a plurality of sub-spectrograms, and smoothness of spectral elements of each sub-spectrogram in the time-frequency domain has directionality on the time-frequency plane. Namely, it is assumed that the spectrogram of acoustic signal is the sum of a plurality of sub-spectrograms each having spectral elements, smoothness of which has different directions in the time frequency domain among sub-spectrograms. The spectral elements belonging to each sub-spectrogram (the same sub-spectrogram) are smooth in substantially the same direction on the time-frequency plane and smoothness directions of the spectral elements of each sub-spectrogram are different with each other. For example, a spectrogram of a polyphonic acoustic signal is assumed to be a sum of a first sub-spectrogram comprised of a set of spectral elements extending in a first direction on the time-frequency plane and a second sub-spectrogram comprised of a set of spectral elements extending in a second direction on the time-frequency plane. In another example, a spectrogram of a polyphonic acoustic signal is assumed to be a sum of a first sub-spectrogram comprised of a set of spectral elements extending in a first direction on the time-frequency plane, a second sub-spectrogram comprised of a set of spectral elements extending in a second direction on the time-frequency plane and a third sub-spectrogram comprised of a set of spectral elements extending in a third direction on the time-frequency plane.

The present invention focuses on the difference of smoothness direction of spectral elements on the spectrogram but it is not necessary to display the spectrogram during processing step for obtaining a separated signal. According to the present invention, it is sufficient that an acoustic signal to be analyzed has been transformed into the time-frequency domain and the spectral elements have been obtained. Method of transformation for the time-frequency domain is typically a Short-Time Fourier Transform but wavelet transform, constant Q filter bank, or other banks of filter analysis may be used. According to one embodiment, the present invention includes a step for transforming an observed acoustic signal into the time-frequency domain and a step for transforming spectral elements of each separated signal into the time domain but all steps of the present invention may be performed in the time-frequency domain. In the actual calculation of spectrogram, spectral elements are obtained at discrete time-frequency. Thus, each spectral element of the spectrogram is defined by a time-frequency bin determined by time bin (frame) and frequency bin.

According to the present invention, a distribution coefficient for distributing spectral elements of acoustic signal is designed typically as a time-frequency mask having a value between 0 and 1 at each time-frequency and separation is conducted by multiplying an input spectrogram by the time-frequency mask. In one embodiment, when a spectrogram of acoustic signal is comprised of two sub-spectrograms, a distribution coefficient for distributing of each spectral element of the acoustic signal to a corresponding spectral element of each sub-spectrogram is a binary mask taking a value 0 or 1. Comfortable hearing of the separated signal may be accomplished with the use of the binary mask. A distribution coefficient is not limited to 0 or 1 but other ratios may be used for distribution. A distribution coefficient or a time-frequency mask can be designed with spectral elements of an input acoustic signal. If a spectrogram of acoustic signal is comprised of three sub-spectrograms, each distribution coefficient may be designed such that the sum of three distribution coefficients becomes 1.

According to one aspect, a distribution coefficient is obtained by: obtaining a likelihood score as a spectral element of each sub-spectrogram based on the directionality of the smoothness of each sub-spectrogram with respect to each spectral element of the acoustic signal, and obtaining the distribution coefficient by using the likelihood score as an index.

According to one aspect, a likelihood score is obtained by: providing filters for extracting characteristics of spectral elements belonging to each sub-spectrogram from the spectrogram of the acoustic signal assuming that the spectrogram of the acoustic signal is an image on the time-frequency plane having values corresponding to energy of each spectral element, and obtaining outputs processed by the filters corresponding to each sub-spectrogram with respect to each spectral element as a score.

According to one aspect, the filter is a low-pass filter for smoothing the values of spectral elements of each sub-spectrogram along the direction of smoothness of spectral elements. It is appreciated by the ordinary skilled person in the art that a filter for extracting the feature of the direction of spectral elements in the smoothness direction is not limited to a digital filter in the frequency domain but can be designed by a spatial filter.

According to one aspect, assuming that the spectrogram of the acoustic signal is the sum of two sub-spectrograms, and the method comprises comparing the scores to obtain a higher score and a lower score, and assigning the distribution coefficient of value 1 to the spectral element having a higher score and the distribution coefficient of value 0 to the spectral element having a lower score. In an alternative embodiment, distribution coefficients may be determined such that the sum of coefficients is equal to zero depending on a ratio between output values from the filters.

In one aspect, the sub-spectrograms include a first sub-spectrogram comprised of spectral elements having smoothness along the frequency direction and a second sub-spectrogram comprised of spectral elements having smoothness along the temporal direction. The filters for extracting characteristics of smoothness direction of spectral elements of each sub-spectrogram include a filter for smoothing substantially along the temporal direction and a filter for smoothing substantially along the frequency direction. More specifically, the filters include a one-dimensional low pass filter only for the temporal direction and a one-dimensional low pass filter only for the frequency direction, or, two two-dimensional filters both of which have much different cutoff frequencies ωt in the temporal direction and (of in the frequency direction (one is ωt>>ωf, the other is ωt<ωf). It is appreciated by the ordinary skilled person in the art that it is possible to design filters for extracting spectral elements where the spectral elements having smoothness in a certain direction in the time-frequency domain even if the direction of spectral element is neither the frequency direction nor the temporal direction. It is also appreciated that it is possible to obtain distribution coefficients using outputs by such filters as an index.

According to one aspect, a distribution coefficient is obtained by: providing an objective function comprising a function of smoothness index of each spectral element distributed to each sub-spectrogram based on the distribution coefficient as parameters, and estimating the parameters for optimizing the objective function. The smoothness index of each distributed spectral element is determined by energy difference between a spectral element of interest and neighboring spectral elements on said time-frequency plane. The neighboring spectral elements of the spectral element of interest are typically immediate adjacent spectral elements but the range of neighborhood is not limited to “immediate adjacent”. Determination of distribution coefficients, or determination of time-frequency masks, is formulated as an optimization problem where the smoothness cost is designed by a function of differential of spectrogram and is minimized.

According to one aspect, the function of smoothness index is as follows:

$${\sum }_{k} {\sum }_{i , j} {f}_{k} ( {\sum }_{m , n} {a}_{m , n}^{( k )} g ( {Q}_{i - m , j - n}^{( k )} ) )$$

where
K: the number of sub-spectrograms;
i: index in the frequency direction;
j: index in the temporal direction;
f_{K}(x): cost function for measuring smoothness;
a_{m,n}: weighting coefficients for neighborhood of a point of interest in the time-frequency domain;
m: index for neighborhood in the frequency direction;
n: index for neighborhood in the temporal direction;
g(x): range-compressed function for spectrogram regarding smoothness index; and
Q^{(K)}_{i,j}: spectral elements of sub-spectrogram.

According to one aspect, the objective function includes a function of distance index between the spectral elements of the acoustic signal and the sum of each spectral element distributed by the distribution coefficient as a parameter. Thus, the objection function is formulated by adding the smoothness cost and the distance index and the distribution coefficients are optimized such that the objective function is minimized.

In one embodiment, the distance index is I-divergence. I-divergence has an advantage in that it is easier to obtain update equations analytically. As for the distance index, as long as update equations for parameters can be analytically obtained, other distance index such as Euclidean Distance (square error) and Mahalanobis distance for example, may be used. Requirements for distribution distance are that at any values of two distributions, a value of function is always non-negative and both of distributions match completely only when the value is zero.

According to one aspect, assuming that the spectrogram of the acoustic signal is the sum of K sub-spectrograms, the objective function is as follows:

$$J = {\sum }_{i , j} D ( φ ( {W}_{i , j} ) , {\sum }_{k} φ ( {Q}_{i , j}^{( k )} ) ) + {\sum }_{k} {\sum }_{i , j} {f}_{k} ( {\sum }_{m , n} {a}_{m , n}^{( k )} g ( {Q}_{i - m , j - n}^{( k )} ) )$$

where
K: the number of sub-spectrograms;
i: index for frequency direction;
j: index for temporal direction;
D(A, B): distance index between function A and function B;
φ(x): range-compressed function for spectrogram regarding distance index;
W_{i,j}): observed spectral elements;
f_{K}(x): cost function for measuring smoothness;
a_{m,n}: weighting coefficients for neighborhood of a point of interest in the time-frequency domain;
m: index for neighborhood in the frequency direction;
n: index for neighborhood in the temporal direction;
g(x): range-compressed function for spectrogram regarding smoothness index; and
Q^{(K)}_{i,j}: spectral elements of sub-spectrogram.

According to one embodiment, the objective function includes the following terms.

$$K = 2$$

$${Q}_{i , j}^{( 1 )} = {P}_{i , j}$$

$${Q}_{i , j}^{( 2 )} = {H}_{i , j}$$

$${f}_{1} ( x ) = \frac{1}{2 {σ}_{P}^{2}} {x}^{2}$$

$${f}_{2} ( x ) = \frac{1}{2 {σ}_{H}^{2}} {x}^{2}$$

$${a}_{m , n}^{( 1 )} = \{ \begin{matrix}- 1 & ( m = 0 , n = 0 ) \\ 1 & ( m = - 1 , n = 0 ) \\ 0 & ( ohterwise )\end{matrix} \\ {a}_{m , n}^{( 2 )} = \{ \begin{matrix}- 1 & ( m = 0 , n = 0 ) \\ 1 & ( m = 0 , n = - 1 ) \\ 0 & ( ohterwise )\end{matrix}$$

According to one embodiment, the objective function includes the following terms.

$$D ( A , B ) = A log \frac{A}{B} - A + B$$

$$φ ( x ) = x$$

$$g ( x ) = {x}^{0.5}$$

The terms correspond to a second embodiment which will be explained hereinafter.

According to one embodiment, the objective function includes the following terms.

$$D ( A , B ) = \{ \begin{matrix}0 & ( A = B ) \\ ∞ & ( A \neq B )\end{matrix} \\ φ ( x ) = {x}^{γ} ( 0 < γ \leq 1 ) \\ g ( x ) = φ ( x )$$

The terms correspond to a third embodiment which will be explained hereinafter.

Embodiments of the present invention adopt an idea for obtaining comfortable hearing of separated sound. Human auditory sense captures volume (acoustic energy) logarithmically (about to the power of 0.3). Therefore, it is possible to recognize change of smaller volume to some extent and if small energy remains, people tend to feel that separation was failed. The second embodiment described hereinafter deals with the problem by (1) handling energy more logarithmically by adopting I-divergence and (2) handling energy more logarithmically by adopting a square root of smoothness cost. According to the third embodiment described hereinafter, smoothness is linearly dealt with. Specifically, energy is range-compressed to the power of 0.3 in advance.

A real-time separation of harmonic/percussion sounds regarding the second and third embodiments is described. Actually, the separation is performed using all input time-frequency elements. The methods of the second and third embodiments require computational time for an iterative operation. However, by defining smoothness between adjacent frames, faster computation is accomplished which results in a real-time operation. Thus, the distribution coefficient is calculated by minimizing smoothness of energy between adjacent time-frequency bins.

Specifically, an iterative operation similar to an EM algorithm is performed by shifting an analyzing section. As is shown in FIG. 9A, when a frame is inputted to a predetermined analyzing spectrogram section, an iterative update is performed in the analyzing spectrogram section, distribution coefficients for a frame to be outputted next is determined and spectral elements distributed by the distribution coefficients are outputted, and transformed into the time domain. Namely, the embodiment comprises the following steps: obtaining spectral elements by transforming the acoustic signal in an initial analyzing section into the time-frequency domain; transforming the acoustic signal in one frame into the time-frequency domain to obtain spectrum elements thereof and adding the spectrum elements of the one frame to the initial analyzing section; estimating parameters using spectral elements of said analyzing section, separating an oldest frame in said analyzing section by using the estimated parameter; and transforming said separated spectral elements into the time-frequency domain.

According to one preferable aspect, an algorithm for estimating distribution coefficients which are parameters in the objective function is an EM (expectation-maximization) algorithm but other optimization algorithms such as steepest descent method and Newton's method may be used. An auxiliary variable may be introduced for solving the EM algorithm.

According to the present invention, the number of sub-spectrograms is any number more than one. In one aspect, a spectrogram of acoustic signal are comprised of two sub-spectrograms, and typically the sub-spectrograms include a first sub-spectrogram comprised of spectral elements having smoothness along the frequency direction and a second sub-spectrogram comprised of spectral elements having smoothness along the temporal direction. In this case, in one embodiment, the acoustic signal is a music signal including percussion sound, and the first sub-spectrogram includes spectral elements of percussion sound. Namely, the first sub-spectrogram relates to a non-harmonic component (typically, percussion sound) and the second sub-spectrogram relates to a harmonic component. Directions of smoothness of spectral elements of sub-spectrogram of the acoustic signal are not limited to the frequency direction and the temporal direction. If the spectral elements have smoothness in a certain direction in the time-frequency domain, it is possible to separate the spectrogram of the acoustic signal into a plurality of sub-spectrograms depending on the direction of smoothness of the spectral elements.

Hardware configuration of the present invention can be comprised of a computer such as a personal computer having an input device, an output device including a display device, a CPU, a memory device such as ROM and RAM, and bus connections for these devices. Therefore, the present invention can be provided in the form of a computer program or a computer-readable medium storing the computer program causing a computer to implement any one of acoustic signal separation methods of claims 1 to 26

The present invention can be provided as an apparatus for separating an acoustic signal. The apparatus comprises means for obtaining a distribution coefficient for distributing spectral elements of said acoustic signal in the time-frequency domain to at least one sub-spectrogram based on the directionality of the smoothness of each sub-spectrogram on the time-frequency plane, and means for separating at least one sub-spectrogram from the spectral elements of said acoustic signal using the distribution coefficient. Typically, the apparatus further comprises means for transforming the acoustic signal into time frequency domain and means for transforming spectral elements corresponding to the separated each sub-spectrogram into time domain. The present invention may comprise means or step for emphasizing or suppressing the spectral elements of at least one separated sub-spectrogram. For example, an equalizer shown in FIG. 11 can be obtained by the present invention. In the specification, numerous equations are used in the following descriptions of embodiment but please note that reference number for equations is assigned independently in each section.

According to the present invention, by utilizing the anisotropy of smoothness of spectral elements in the time-frequency domain, it is possible to obtain a separated signal from a polyphonic signal without using trained data or prior information.

According to the present invention, it is possible to separate percussion sound from an acoustic signal without using trained data or information particular to a music instrument such as percussion template.

### BRIEF DESCRIPTION OF THE DRAWINGS

FIG. 1 shows an example of spectrogram of popular music in which magnitude of spectral element is represented by gray-scale.

FIG. 1A shows a three dimensional representation of spectrogram. Spectral elements having smoothness along the temporal direction (a right side axis in the drawing) and spectral elements having smoothness along the frequency direction (a left side axis in the drawing) can be observed. FIG. 1A is independent of FIG. 1 and relates to different spectral elements.

FIG. 2 shows a model of an observed time-frequency spectrogram.

FIG. 3 (left) shows a spectrogram of harmonic sound comprised of spectral elements which are smooth in the temporal direction and steep in the frequency direction. FIG. 3 (right) shows a spectrogram of percussion sound comprised of spectral elements which are smooth in the frequency direction and steep in the temporal direction. The spectral elements in the left view and the spectral elements in the right view are sparsely presented on the time-frequency plane.

FIG. 4 shows separation of an input spectrogram by multiplying the spectrogram by a time-frequency mask.

FIG. 5 is a block diagram showing a first embodiment.

FIG. 6 shows filters used in the first embodiment in which a left view relates to a feature extraction filter for H(x, y) and a right view relates to a feature extraction filter for P(x, y).

FIG. 7 shows sectional shapes of the filters shown in FIG. 6. According to the feature extraction filter for H(x, y), the horizontal axis relates to temporal elements obtained by two dimensional Fourier transformation. According to the feature extraction filter for P(x, y), the horizontal axis relates to frequency elements obtained by two-dimensional Fourier transform. The vertical axis shows the size of filter and as with a larger filter, more corresponding elements can pass through. Both of triangle window and Gaussian window are low pass filters because central portion is set to zero.

FIG. 8 is a block diagram showing a second embodiment.

FIG. 9A is a view explaining real-time separation of harmonic/percussion sounds.

FIG. 9B shows a stage of separation process in real-time separation of harmonic/percussion sounds. In the displayed spectrogram, at the side of older frames, it can b obverted that spectral elements that are smooth along the frequency direction are extracted.

FIG. 9C shows a stage of separation process in real-time separation of harmonic/percussion sounds. In the displayed spectrogram, at the side of older frames, it can be obverted that spectral elements that are smooth along the temporal direction are extracted.

FIG. 10 shows spectrograms of harmonic component (left) and percussive component (right) which are iteratively-undated at k=0, K=3, K=10, K=50, and after binarization, from top to bottom, respectively, according to a third embodiment method.

FIG. 11 shows a GUI (Graphical User Interface) screen of real-time separation system of harmonic/percussion sounds in which Method 1 corresponds to the method of the first embodiment and Method 2 corresponds to the method of the second embodiment.

### DETAILED DESCRIPTION

### [A] Summary of Embodiments

According to one embodiment of the invention, music signals having mixed harmonic sound and percussion sound are analyzed. Let W(x, t) be a spectrogram obtained by the Short-Time Fourier Transform of an input signal where x denotes “frequency” and t denotes “time”. An object of the embodiment is to decompose the spectrogram W(x, t) into two spectrograms, namely, a non-harmonic component P(x, t) such as percussion sound without having a pitch interval and a harmonic components H(x, t) such as sound of instruments having a pitch interval.

At any time-frequency (x, t), the following inequalities and an equation have to be satisfied.

P(x,t)≧0 (1)

H(x,t)≧0 (2)

P(x,t)+H(x,t)=W(x,t) (3)

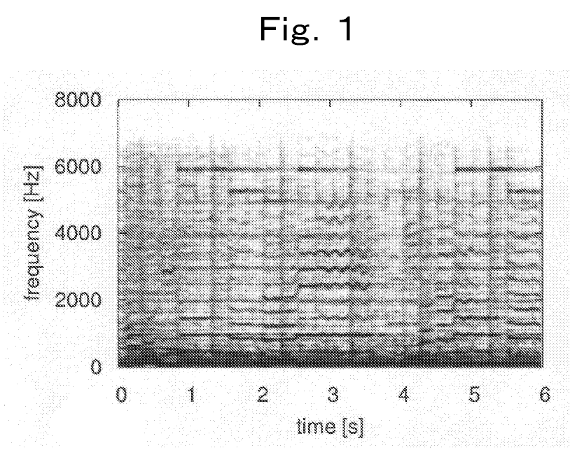

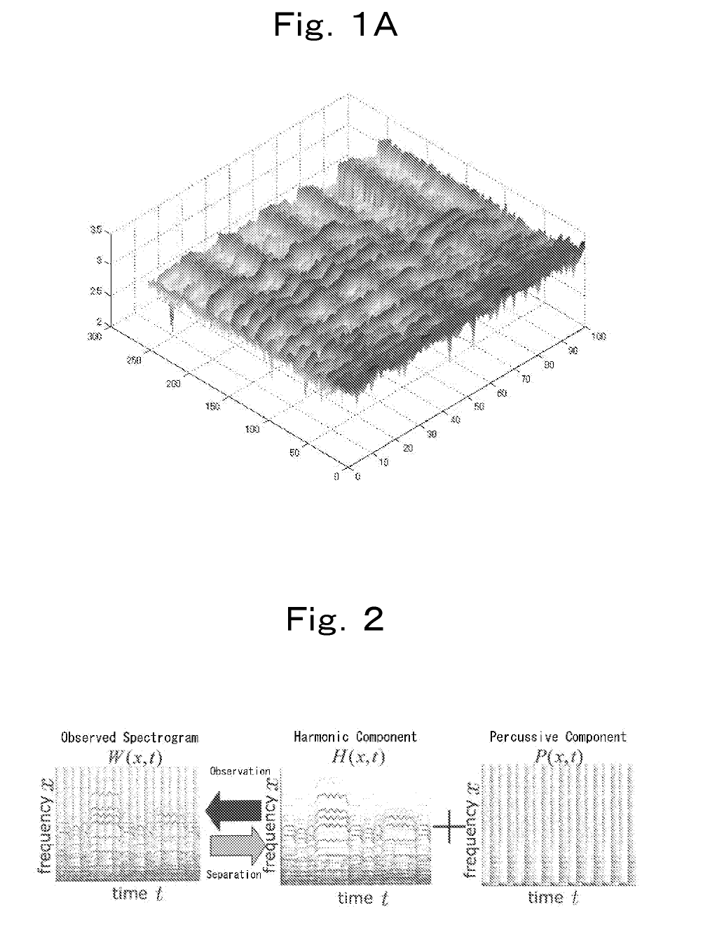

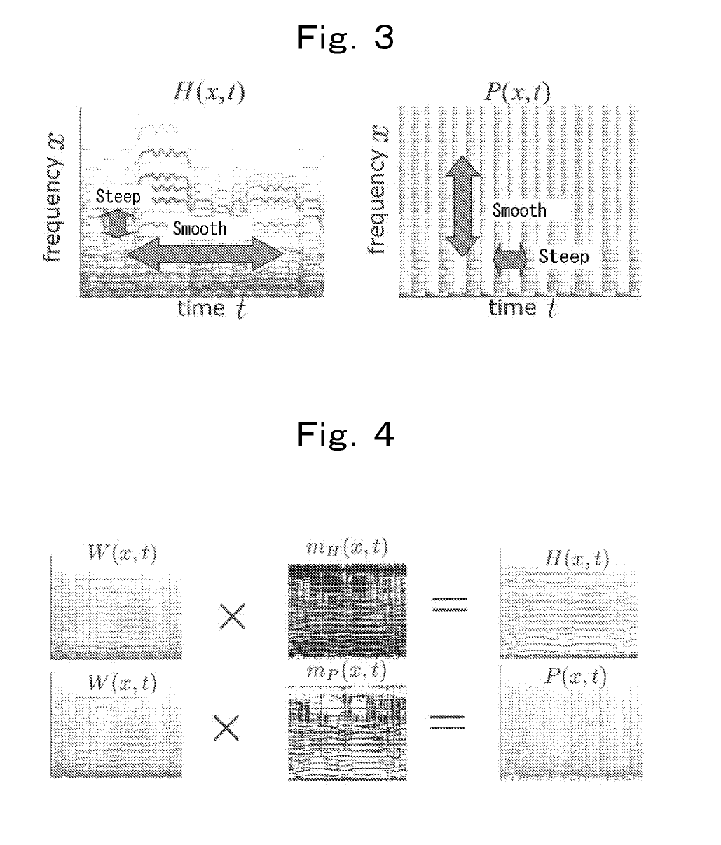

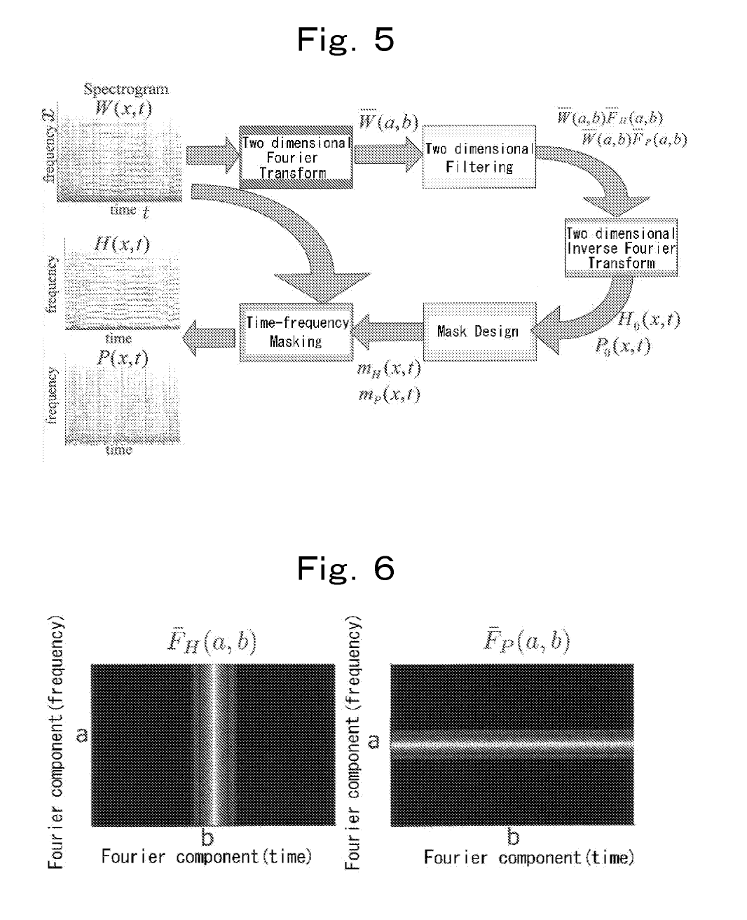

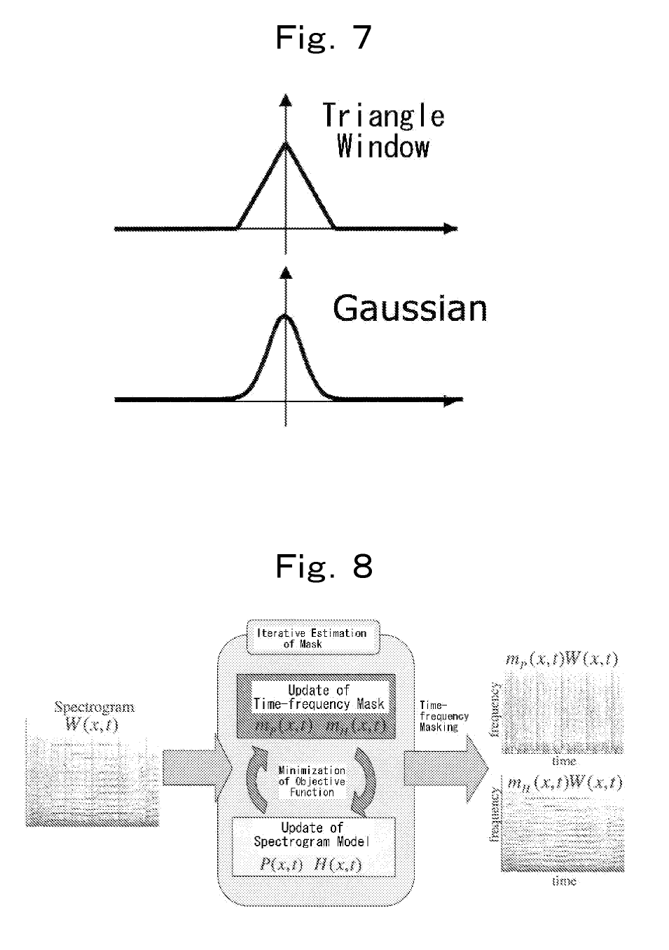

According to the embodiment, we focus on the anisotropy of harmonic component and percussive component. More specifically, as shown in FIG. 1, it is noted that a spectrogram of the music signal of popular music in the time-frequency domain often comprises spectral elements in the form of mountains or ridges extended along the frequency direction and spectral elements in the form of mountains or ridges extended along the temporal direction. The former corresponds to the component P(x, t) which has smoothness (broadness) along the frequency direction but has steepness along the temporal direction, and the latter corresponds to component H(x, t) which has steepness along the frequency direction but has smoothness along the temporal direction. Both components are distributed sparsely (less likely, occurred on the same time-frequency bin) on the time-frequency plane

According to the embodiment, the spectrogram of input signal is separated into two spectrograms by a time-frequency mask. Based on sparseness of P(x, t) and H (x, t), by designing time-frequency masks m_{P}(x, t) and m_{H}(x, t) each having a value between 0 and 1 at any time-frequency, W(x, t) can be separated.

P(x,t)=m_{P}(x,t)W(x,t) (4)

H(x,t)=m_{H}(x,t)W(x,t) (5)

∀x,t,1=m_{P}(x,t)+m_{H}(x,t) (6)

The separated spectrograms meet characteristics of inequalities (1) and (2) and an equation (3).

A time-frequency mask is designed to detect direction of smoothness of spectral elements forming a sub-spectrogram. According to the embodiment, time-frequency masks are designed to separate the spectrogram of the input signal into respective spectral elements by using characteristics where the spectral elements of percussive component have smoothness in the frequency direction and the spectral elements of harmonic component have smoothness in the temporal direction. In one aspect, the time-frequency mask having a value between 0 and 1 is a binary mask having a value 0 or 1.

As foregoing, according to the embodiment, the music signal is separated at high speed by actively utilizing the difference in characteristics on a time-frequency plane where, on the time-frequency spectrogram of the music signal, the harmonic component has smoothness in the temporal direction and the percussive component has smoothness in the frequency direction. More specifically, a given time-frequency spectrogram is separated into harmonic/percussive components by designing complementarily time-frequency masks to separate the given time-frequency spectrogram, and then applying masking operation by the time-frequency mask to the time-frequency spectrogram of the music signal. As a method of designing the mask, three embodiments will be described including (1) a method of using two-dimensional filters, (2) a method of minimizing divergence and smoothness cost by an algorithm similar to an EM algorithm, and (3) a method of minimizing smoothness cost as to a range-compressed spectrogram by an algorithm similar to an EM algorithm. In the description of each embodiment, an equation number is applied independently for each embodiment.

### [B] First Embodiment

According to the first embodiment, a spectrogram of an observed signal on time-frequency plane is assumed to be an image. Two-dimensional filters utilizing the difference in characteristics of harmonic sound and percussion sound are used to separate the percussion sound and the harmonic sound from the music signal without information particular to a music instrument.

### [B-1] Mask Design by Using Outputs of Two-Dimensional Filters

Design of time-frequency masks m_{P}(x, t) and m_{H}(x, t) will be explained. Assuming that W(x, t) is an image, by applying two-dimensional filters for respectively extracting characteristics of P(x, t) and H(x, t), namely, edges along the frequency direction (vertical edges) and edges along the temporal direction (horizontal edges), it is possible to determine whether each time-frequency element belongs to P(x, t) or H(x, t) based on greater/smaller output results from filters.

Let two-dimensional Fourier-Transformed components of W(x, t) be W(supra bar)(a, b) (a: Fourier components in frequency direction, b: Fourier components in temporal direction), output results from the filters can be obtained as follows:

P₀(x,t)=IFT[ W̅(a,b)× F̅_{P}(a,b)] (7)

H₀(x,t)=IFT[ W̅(a,b)× F̅_{H}(a,b)] (8)

where F(supra bar)_{H}(a, b) is a feature extraction filter for P(x, t), and F(supra bar)_{H}(a, b) is a feature extraction filter for H(x, t). Based on the results, the time-frequency masks M_{P}(x, t) and m_{H}(x, t) can be obtained as follows:

$$\begin{matrix}{m}_{P} ( x , t ) = \{ \begin{matrix}1 & ( {P}_{0} ( x , t ) > {H}_{0} ( x , t ) ) \\ 0 & ( otherwise )\end{matrix} & ( 9 ) \\ {m}_{H} ( x , t ) = 1 - {m}_{P} ( x , t ) & ( 10 )\end{matrix}$$

### [B-2] Design of Two-Dimensional Feature Extraction Filters

Requirements for the two-dimensional filters will be considered. If the output results become indices for P(x, t)-likeliness and H(x, t)-likeliness for each time-frequency element, desirably, the filtering output is non-negative real number (It is not necessary to be non-negative though). Time-frequency of input spectrogram and time-frequency of filtered output corresponds to each other. For the former requirement, the filter has any shape represented by convolution of any two dimensional distributions A(a, b)*A(a, b). If the shape of the filter is real number distribution symmetric to both a and b axes, the latter requirement is also satisfied.

Various shapes can be employed for the two-dimensional filters F(supra bar)_{P}(a, b) and F(supra bar)_{H}(a, b) for respectively extracting characteristics of P (x, t) and H(x, t). In the following example, as simplest filters satisfying the requirements, low pass filters are designed.

F_{P}(a,b)=g(a) (11)

F_{H}(a,b)=h(b) (12)

F_{P}(a, b) is a low pass filter only for frequency direction and F_{H}(a, b) is a low pass filter only for temporal direction. As sectional shapes of one dimensional filters g(a) and h(b), triangle window or Gaussian can be employed.

Triangle window-typed low pass filter can be described as

$$\begin{matrix}{\overline{F}}_{P} ( a , b ) = \{ \begin{matrix}( 1 - \frac{a}{{σ}_{P}} ) & ( 0 \leq a < {σ}_{P} ) \\ ( 1 + \frac{a}{{σ}_{P}} ) & ( - {σ}_{P} \leq a < 0 ) \\ 0 & ( otherwise )\end{matrix} & ( 13 ) \\ {\overline{F}}_{H} ( a , b ) = \{ \begin{matrix}( 1 - \frac{b}{{σ}_{H}} ) & ( 0 \leq b < {σ}_{H} ) \\ ( 1 + \frac{b}{{σ}_{H}} ) & ( - {σ}_{H} \leq b < 0 ) \\ 0 & ( otherwise )\end{matrix} & ( 14 )\end{matrix}$$

Gaussian window-typed filter can be described as

$$\begin{matrix}{\overline{F}}_{P} ( a , b ) = {e}^{- \frac{{a}^{2}}{2 {σ}_{P}^{2}}} & ( 15 ) \\ {\overline{F}}_{H} ( a , b ) = {e}^{- \frac{{b}^{2}}{2 {σ}_{H}^{2}}} & ( 16 )\end{matrix}$$

P₀(x, t) and H₀(x, t) are obtained by two-dimensional inverse Fourier transform of components passed through the filters and the time-frequency masks m_{P}(x, t) and m_{H}(x, t) can be designed.

Two-dimensional filter is one of the simplest filtering shapes for satisfying the requirements. A triangle window can be represented by convolution of two rectangular windows and a Gaussian window can be represented by convolution of two Gaussians so that filtered outputs of these filters are non-negative. By using these two-dimensional filters, components having smoothness in temporal direction/frequency direction can be passed through respectively. By comparing two non-negative values as output results for each time-frequency bin, it can be determined whether the bin of interest is harmonic-like or percussive-like. As a parameter of filter, parameters σ_{P} and σ_{H} corresponding to cutoff frequency of low pass filter can be considered. The smaller the parameter values are, only the smoother elements can pass through. Considering impulse response of proposed two-dimensional filters, one direction of time and frequency directions corresponding to “not low pass” is delta function and the other is square of the sinc function (in the case of triangle window type) or Gaussian (in the case of Gaussian window type). This filtering process is to take a weighted average in either frequency direction or temporal direction on a spectrogram of a target time-frequency bin. An operation for taking any weighted average in the neighborhood of each time-frequency bin corresponds with filtering using positive definite filters. If the impulse response of filter is symmetric with respect to both time axis and frequency axis (or even function with respect to both time and frequency), there is no unevenness of weighted average regarding time/frequency elements so that mismatch between the separated spectrogram and the original spectrogram does not occur. Because of this nature, it is appropriate to design the mask function from the output result from the filter.

### [B-3] Experimental Evaluations

### [B-3-1] Results of Application to Actual Music

Separation experiments using popular song music were conducted. An input signal was chosen from RWC Music Database and RWC-MDB-P-2001 No. 7 was used (sampling: 16 kHz). A spectrogram of an input signal, separation results by the proposed algorithm (the shaped of low pass filter is Gaussian) are shown in the left portion of FIG. 5.

It is observed that P(x, t) was separated as elements broad along the frequency direction and H(x, t) was separated as elements having smoothness along the temporal direction but steepness along the frequency direction. In auditory evaluation of the separated sound, the percussion sound such as snare drum is separated as P(x, t) but bass drum and high-hat (especially, duration part) are separated as H(x, t). Regarding voices, continuous pitch-varying part may be separated either P(x, t) or H(x, t) but more likely separated as H(x, t) by adjusting cutoff frequency of low pass filter.

### [B-3-2] Quantitative Evaluation by Using MIDI

Quantitative evaluation of the proposed algorithm was conducted. As an input signal, the prelude of RWC-MDB-P-2001 No. 18 was used. MIDI formatted data is separated into each part and each part was converted to WAV format and then summation of these signals was used as an input (sampling: 16 kHz). Energy ratios included in P(x, t) and H(x, t) is obtained by calculating cross-correlation between each part signal and a separated signal according to the method of the first embodiment. The result is shown in Table 1. As shown in the table, melody and accompaniment such as guitar and piano are separated as H(x, t), snare drum and high-hat are separated as P(x, t) and bass drum is separated as H(x, t).

TABLE 1
ENERGY RATIO OF EACH INSTRUMENTAL PART

| Part | Ratio for P | Ratio for H |
|---|---|---|
| piano | 0.24 | 0.76 |
| bass | 0.19 | 0.81 |
| synthesizer | 0.25 | 0.75 |
| electric guitar | 0.09 | 0.91 |
| brass | 0.38 | 0.62 |
| snare drum | 0.92 | 0.08 |
| high-hat | 0.93 | 0.07 |
| bass drum | 0.04 | 0.96 |

The first embodiment uses continuousness in frequency and temporal directions of the spectrogram as characteristics of percussion sound and harmonic sound. It is suitable to separate percussion sound such as sound of snare drum and sounds of pitched music instruments. Separation of percussion sounds of bass drum and high-hat having a relatively long tone and an uneven frequency distribution, piano sound or bass sound, and voice having variable pitches can be dealt with designs of shapes of feature extraction two-dimensional filters.

### [C] Second Embodiment

As a separation method of music signal without utilizing information regarding scores and instruments, the first embodiment provides a fast computational method using the two dimensional filters on the spectrogram similar to those used in an image processing. According to the second embodiment, an iterative solution by an EM algorithm based on the anisotropy of smoothness of spectrogram is proposed and evaluation of computational time and performance is conducted. A real-time separation system using the algorithm of the second embodiment is also proposed.

### [C-1] Introduction of Smoothness Cost

We discuss the solution to estimate H(x, t) and P(x, t) from W(x, t) using anisotropy of harmonic component and percussive component on the spectrogram. In the actual implementation, (x, t) can be obtained as discrete coordinates so that (x, t) is defined as a discrete time-frequency area (xᵢ, tⱼ) in the following discussion (i: frequency bin number, j: analyzing frame number).

According to the embodiment, the anisotropy of smoothness of spectrogram is considered as a cost to be minimized and is represented as a squared difference of a square root of energy between neighboring time-frequency bins as follows:

$$\begin{matrix}{Ω}_{H} = \frac{1}{2 {σ}_{H}^{2}} {\sum }_{i = 1}^{I} {\sum }_{j = 1}^{J - 1} {( \sqrt{H ( {x}_{i} , {t}_{j + 1} )} - \sqrt{H ( {x}_{i} , {t}_{j} )} )}^{2} & ( 1 ) \\ {Ω}_{P} = \frac{1}{2 {σ}_{P}^{2}} {\sum }_{i = 1}^{I - 1} {\sum }_{j = 1}^{J} {( \sqrt{P ( {x}_{i + 1} , {t}_{j} )} - \sqrt{P ( {x}_{i} , {t}_{j} )} )}^{2} & ( 2 )\end{matrix}$$

By taking the square root, a formulation of smoothness cost which resembles human auditory characteristics logarithmically capturing energy is obtained.

### [C-2] Iteration Estimation of Parameters by Minimizing an Objective Function

### [C-2-1] Summary

Time-frequency masks m_{P}(xᵢ, tⱼ) and m_{H}(xᵢ, tⱼ) for distributing an observed spectrogram to harmonic component and percussive component are introduced. Time-frequency masks m_{P}(xᵢ, tⱼ) and m_{H}(xᵢ, tⱼ) satisfy the conditions defined in Section [A].

I-divergence is employed as an index for distribution distance to represent nearness between distributed energy m_{P}(xᵢ, tⱼ)W(xᵢ, tⱼ) and P(xᵢ, tⱼ) and between distributed energy m_{H}(xᵢ, tⱼ)W(xᵢ, tⱼ) and H(xᵢ, tⱼ). We can formulate the solution as minimizing an objective function including the sum of I-divergence and smoothness costs defined in equations (1) and (2).

$${\sum }_{i , j} {m}_{P} ( {x}_{i} , {t}_{j} ) W ( {x}_{i} , {t}_{j} ) log ( \frac{{m}_{P} ( {x}_{i} , {t}_{j} ) W ( {x}_{i} , {t}_{j} )}{P ( {x}_{i} , {t}_{j} )} ) + {\sum }_{i , j} {m}_{H} ( {x}_{i} , {t}_{j} ) W ( {x}_{i} , {t}_{j} ) log ( \frac{{m}_{H} ( {x}_{i} , {t}_{j} ) W ( {x}_{i} , {t}_{j} )}{H ( {x}_{i} , {t}_{j} )} ) - {\sum }_{i , j} ( W ( {x}_{i} , {t}_{j} ) - P ( {x}_{i} , {t}_{j} ) - H ( {x}_{i} , {t}_{j} ) ) + {Ω}_{H} + {Ω}_{P} \qquad ( 3 )$$

By alternately updating H(xᵢ, tⱼ) and P(xᵢ, tⱼ) by minimizing equation (3) with the time-frequency masks fixed and updating m_{H}(xᵢ, tⱼ) and m_{P}(xᵢ, tⱼ) by minimizing equation (3) with H(x, t) and P(x, t) fixed, a local optimal solution for minimization of the objective function (3) can be obtained. An iterative solution using I-divergence will be explained in the followings.

### [C-2-2] Solution Using Squared Difference of Energy as Smoothness Cost

The iterative solution using I-divergence is described in detail. In the following description, for the purpose of convenient explanation, equation number is assigned independently of other sections. An object here is to separate an input spectrogram W(x, t) (x: frequency, t: time frame) into percussive component P(x, t) and harmonic component (x, t). A method of iteratively estimating P(x, t) and H(x, t) by an EM algorithm using time-frequency masks m_{P}(x, t) and m_{H}(x, t) will be explained. I-divergence is adopted as a distance between distributions for indicating nearness between W(x, t) and P(x, t)+H(x, t). This distance index (I-divergence) can handle energy more logarithmically and ignore errors regarding very small energy in comparison with the squared-error of logarithm and therefore has an affinity with human auditory characteristics. The distance index is non-negative and is equal to zero if W(x, t)=P(x, t)+H(x, t). An objective function J₁ is obtained by adding the distribution distance and terms representing smoothness of H and P. The separation problem is formulated by minimizing the objective function J₁. According to Jensen's inequality, the following relationships are satisfied.

$${J}_{1} = \int \int W ( x , t ) log ( \frac{W ( x , t )}{P ( x , t ) + H ( x , t )} ) - ( W ( x , t ) - P ( x , t ) - H ( x , t ) ) d x d t + {Ω}_{P} + {Ω}_{H} = \int \int - W ( x , t ) log ( \frac{P ( x , t ) + H ( x , t )}{W ( x , t )} ) - ( W ( x , t ) - P ( x , t ) - H ( x , t ) ) d x d t + {Ω}_{P} + {Ω}_{H} = \int \int - W ( x , t ) log ( {m}_{P} ( x , t ) \frac{P ( x , t )}{{m}_{P} ( x , t ) W ( x , t )} + {m}_{H} ( x , t ) \frac{H ( x , t )}{{m}_{H} ( x , t ) W ( x , t )} ) - ( W ( x , t ) - P ( x , t ) - H ( x , t ) ) d x d t + {Ω}_{P} + {Ω}_{H} \leq \int \int m ( x , t ) W ( x , t ) log ( \frac{{m}_{P} ( x , t ) W ( x , t )}{P ( x , t )} ) + {m}_{H} ( x , t ) W ( x , t ) log ( \frac{{m}_{H} ( x , t ) W ( x , t )}{H ( x , t )} ) d x d t - \int \int W ( x , t ) - P ( x , t ) - H ( x , t ) d x d t + {Ω}_{P} + {Ω}_{H} = {J}_{2} \qquad ( 1 )$$

Here, the introduced mask functions m_{P}(x, t) and m_{H}(x, t) have constraints as follows:

∀x,t,m_{P}(x,t)+m_{H}(x,t)=1 (2)

The above equality satisfies only if

$${m}_{P} ( x , t ) = \frac{P ( x , t )}{P ( x , t ) + H ( x , t )} \\ {m}_{H} ( x , t ) = \frac{H ( x , t )}{P ( x , t ) + H ( x , t )} \qquad ( 3 )$$

Ω_{P} and Ω_{H} are constraints regarding smoothness, and can be defined by squared difference between neighboring time-frequency elements as follows:

$$\begin{matrix}{Ω}_{P} = \frac{1}{2 {σ}_{P}^{2}} {\sum }_{i = 1}^{I - 1} {\sum }_{j = 1}^{J} {\vert P ( {x}_{i + 1} , {t}_{j} ) - P ( {x}_{i} , {t}_{j} ) \vert}^{2} & ( 4 ) \\ {Ω}_{H} = \frac{1}{2 {σ}_{H}^{2}} {\sum }_{i = 1}^{I} {\sum }_{j = 1}^{J - 1} {\vert H ( {x}_{i} , {t}_{j + 1} ) - H ( {x}_{i} , {t}_{j} ) \vert}^{2} & ( 5 )\end{matrix}$$

In inequality (1), P(x, t) and H(x, t) are estimated by minimizing J₂ with mask functions m_{P}(x, t) and m_{H}(x, t) fixed, and then the masks are updated by equation (3) with P(x, t) and H(x, t) fixed. It is assured that the objective function J₁ monotonically decreases by alternately iterating the two steps for updating parameters. A solution can be converged on a local optimal solution because J₁≧0.

X and t of actual data are discrete and update equation can be derived from a discrete model. Partial derivatives of J₂ by P(xᵢ, tⱼ)=P_{i,j}, and H(xᵢ, tⱼ)=Hi_{,j}, are as follows:

$$\begin{matrix}\frac{\partial {J}_{2}}{\partial {P}_{i , j}} = \{ \begin{matrix}- \frac{{m}_{P , i , j} {W}_{i , j}}{{P}_{i , j}} + \frac{1}{{σ}_{P}^{2}} ( \begin{matrix}2 {P}_{i , j} - \\ ( {P}_{i - 1 , j} + {P}_{i + 1 , j} )\end{matrix} ) + 1 & ( \begin{matrix}2 \leq i \leq \\ I - 1\end{matrix} ) \\ - \frac{{m}_{P , i , j} {W}_{i , j}}{{P}_{i , j}} + \frac{1}{{σ}_{P}^{2}} ( {P}_{i , j} - {P}_{i + 1 , j} ) + 1 & ( i = 1 ) \\ - \frac{{m}_{P , i , j} {W}_{i , j}}{{P}_{i , j}} + \frac{1}{{σ}_{P}^{2}} ( {P}_{i , j} - {P}_{i - 1 , j} ) + 1 & ( i = I )\end{matrix} & ( 6 ) \\ \frac{\partial {J}_{2}}{\partial {H}_{i , j}} = \{ \begin{matrix}- \frac{{\dot{m}}_{H , i , j} {W}_{i , j}}{{H}_{i , j}} + \frac{1}{{σ}_{H}^{2}} ( \begin{matrix}2 {H}_{i , j} - \\ ( {H}_{i , j - 1} + {H}_{i , j + 1} )\end{matrix} ) + 1 & ( \begin{matrix}2 \leq j \leq \\ J - 1\end{matrix} ) \\ - \frac{{\dot{m}}_{H , i , j} {W}_{i , j}}{{H}_{i , j}} + \frac{1}{{σ}_{H}^{2}} ( {H}_{i , j} - {H}_{i , j + 1} ) + 1 & ( j = 1 ) \\ - \frac{{m}_{H , i , j} {W}_{i , j}}{{H}_{i , j}} + \frac{1}{{σ}_{H}^{2}} ( {H}_{i , j} - {H}_{i , j - 1} ) + 1 & ( j = J )\end{matrix} & ( 7 )\end{matrix}$$

Solving the partial derivatives as being equal to zero to obtain two solutions of quadratic equation for P_{i,j}, H_{i,j}, and P_{i,j} and H_{i,j} are positive, and then the following equations can be obtained.

$$\begin{matrix}{\hat{P}}_{i , j} = \frac{{b}_{P , i , j} + \sqrt{{b}_{P , i , j}^{2} + 4 {a}_{P , i , j } {c}_{P , i , j}}}{2 {a}_{Pi , j}} & ( 8 ) \\ {a}_{P , i , j} = \{ \begin{matrix}\frac{2}{{σ}_{P}^{2}} & ( 2 \leq i \leq I - 1 ) \\ \frac{1}{{σ}_{P}^{1}} & ( otherwise )\end{matrix} & ( 9 ) \\ {b}_{P , i , j} = \{ \begin{matrix}\frac{1}{{σ}_{P}^{2}} ( {P}_{i - 1 , j} + {P}_{i + 1 , j} ) - 1 & ( 2 \leq i \leq I - 1 ) \\ \frac{1}{{σ}_{P}^{2}} {P}_{i + 1 , j} - 1 & ( i = 1 ) \\ \frac{1}{{σ}_{P}^{2}} {P}_{i - 1 , j} - 1 & ( i = I )\end{matrix} & ( 10 ) \\ {c}_{P , i , j} = {m}_{P , i , j} {W}_{i , j} & ( 11 ) \\ {\hat{H}}_{i , j} = \frac{{b}_{H , i , j} + \sqrt{{b}_{H , i , j}^{2} + 4 {a}_{H , i , j} {c}_{H , i , j}}}{2 {a}_{H , i , j}} & ( 12 ) \\ {\dot{a}}_{H , i , j} = \{ \begin{matrix}\frac{2}{{σ}_{H}^{2}} & ( 2 \leq j \leq J - 1 ) \\ \frac{1}{{σ}_{H}^{2}} & ( otherwise )\end{matrix} & ( 13 ) \\ {b}_{H , i , j} = \{ \begin{matrix}\frac{1}{{σ}_{H}^{2}} ( {H}_{i , j - 1} + {H}_{i , j + 1} ) - 1 & ( 2 \leq j \leq J - 1 ) \\ \frac{1}{{σ}_{H}^{2}} {H}_{i , j + 1} - 1 & ( j = 1 ) \\ \frac{1}{{σ}_{H}^{2}} {H}_{i , j - 1} - 1 & ( j = J )\end{matrix} & ( 14 ) \\ {c}_{H , i , j} = {m}_{H , i , j} {W}_{i , j} & ( 15 )\end{matrix}$$

An iterative estimation algorithm is as follows.

1. Set initial P(xᵢ, tⱼ) and H(xᵢ, tⱼ)
2. Update m_{P}(xᵢ, tⱼ) and m_{H}(xᵢ, tⱼ) at (3)
3. Update P(xᵢ, tⱼ) and H(xᵢ, tⱼ) at (8), (12)
4. End if converge, return to 2 if not

Final separated results can be obtained by using masks m_{P}(x, t) and m_{H}(x, t).

Pₒᵤₜ(x,t)=m_{P}(x,t)W(x,t) (16)

Hₒᵤₜ(x,t)=m_{H}(x,t)W(x,t) (17)

[symbol]

(18)

Considering the auditory sense, comfortable hearing may be obtained by using a binary mask and the separation is conducted by binarizing the estimated masks.

$$\begin{matrix}{P}_{out} ( x , t ) = \frac{{{m}_{P} ( x , t )}^{q}}{{{m}_{P} ( x , t )}^{q} + {{m}_{H} ( x , t )}^{q}} W ( x , t ) & ( 19 ) \\ {H}_{out} ( x , t ) = \frac{{{m}_{H} ( x , t )}^{q}}{{{m}_{P} ( x , t )}^{q} + {{m}_{H} ( x , t )}^{q}} W ( x , t ) & ( 20 ) \\ \text{?} \\ \text{?} \text{indicates text missing or illegible when filed} & ( 21 )\end{matrix}$$

Binarization is more effective with a larger q and if q→∞, the estimated masks become the binary masks.

### [C-2-3] Introduction of Constraint for Smoothness Considering Auditory Characteristics

According to the constraint for smoothness of the previous section, smoothness is defined by considering that small energy part and large energy part are even. However, human auditory sense tends to capture energy logarithmically which could affect the performance of separation. Therefore, constraint may be given as squared difference of a square root of energy as follows.

$$\begin{matrix}{Ω}_{P} = \frac{1}{2 {σ}_{P}^{2}} {\sum }_{i = 1}^{I - 1} {\sum }_{j = 1}^{J} {( \sqrt{P ( {x}_{i + 1} , {t}_{j} )} - \sqrt{P ( {x}_{i} , {t}_{j} )} )}^{2} & ( 22 ) \\ {Ω}_{H} = \frac{1}{2 {σ}_{H}^{2}} {\sum }_{i = 1}^{I} {\sum }_{j = 1}^{J - 1} {( \sqrt{H ( {x}_{i} , {t}_{j + 1} )} - \sqrt{H ( {x}_{i} , {t}_{j} )} )}^{2} & ( 23 )\end{matrix}$$

According to the equations, the smoothness is defined by considering that acoustic energy is captured more logarithmically. If energy of analyzing signal is multiplied by a scale of constant A, for example, W(x, t), P(x, t) and H(x, t) are multiplied by A, not only 1-divergence but also the above-mentioned cost is multiplied by A. It is not necessary to change parameters σ_{P} and σ_{H} for music at different volumes. Auditorily, it has an affinity with I-divergence that is distribution distance index dealing with magnitude logarithmically.

Update equation using the cost is considered. Partial derivative of the objective function by P(xᵢ, tⱼ)=p_{i,j} is as follows:

$$\frac{\partial {J}_{2}}{\partial {P}_{i , j}} = \{ \begin{matrix}- \frac{{m}_{P , i , j} {W}_{i , j}}{{P}_{i , j}} + \frac{1}{2 {σ}_{P}^{2} \sqrt{{P}_{i , j}}} ( 2 \sqrt{{P}_{i , j}} - ( \sqrt{{P}_{i - 1 , j}} + \sqrt{{P}_{i + 1 , j}} ) ) + 1 & ( 2 \leq i \leq I - 1 ) \\ - \frac{{m}_{P , i , j} {W}_{i , j}}{{P}_{i , j}} + \frac{1}{2 {σ}_{P}^{2} \sqrt{{P}_{i , j}}} ( \sqrt{{P}_{i , j}} - \sqrt{{P}_{i + 1 , j}} ) + 1 & ( i = 1 ) \\ - \frac{{m}_{P , i , j} {W}_{i , j}}{{P}_{i , j}} + \frac{1}{2 {σ}_{P}^{2} \sqrt{{P}_{i , j}}} ( \sqrt{{P}_{i , j}} - \sqrt{{P}_{i - 1 , j}} ) + 1 & ( i = I )\end{matrix}$$

Solving P_{i,j} by partial derivative as being equal to zero, the following equations are obtained.

$$\begin{matrix}{\hat{P}}_{i , j} = {( \frac{{b}_{P , i , j} + \sqrt{{b}_{P , i , j}^{2} + 4 {a}_{P , i , j} {c}_{P , i , j}}}{2 {a}_{P , i , j}} )}^{2} & ( 25 ) \\ {a}_{P , i , j} = \{ \begin{matrix}\frac{2}{{σ}_{P}^{2}} + 2 & ( 2 \leq i \leq I - 1 ) \\ \frac{1}{{σ}_{P}^{2}} + 2 & ( otherwise )\end{matrix} & ( 26 ) \\ {b}_{P , i , j} = \{ \begin{matrix}\frac{( \sqrt{{P}_{i - 1 , j}} + \sqrt{{P}_{i + 1 , j}} )}{{σ}_{P}^{2}} & ( 2 \leq i \leq I - 1 ) \\ \frac{\sqrt{{P}_{i + 1 , j}}}{{σ}_{P}^{2}} & ( i = 1 ) \\ \frac{\sqrt{{P}_{i - 1 , j}}}{{σ}_{P}^{2}} & ( i = I )\end{matrix} & ( 27 ) \\ {C}_{P , i , j} = 2 {m}_{P , i , j} {W}_{i , j} & ( 28 )\end{matrix}$$

Similarly, regarding H_{i,j} the following equations are obtained.

$$\begin{matrix}{\hat{H}}_{i , j} = {( \frac{{b}_{H , i , j} + \sqrt{{b}_{H , i , j}^{2} + 4 {a}_{H , i , j} {c}_{H , i , j}}}{2 {a}_{H , i , j}} )}^{2} & ( 29 ) \\ {a}_{H , i , j} = \{ \begin{matrix}\frac{2}{{σ}_{H}^{2}} + 2 & ( 2 \leq i \leq I - 1 ) \\ \frac{1}{{σ}_{H}^{2}} + 2 & ( otherwise )\end{matrix} & ( 30 ) \\ {b}_{H , i , j} = \{ \begin{matrix}\frac{( \sqrt{{H}_{i , j - 1}} + \sqrt{{H}_{i , j + 1}} )}{{σ}_{H}^{2}} & ( 2 \leq j \leq J - 1 ) \\ \frac{\sqrt{{H}_{i , j + 1}}}{{σ}_{H}^{2}} & ( j = 1 ) \\ \frac{\sqrt{{H}_{i , j - 1}}}{{σ}_{H}^{2}} & ( j = J )\end{matrix} & ( 31 ) \\ {C}_{H , i , j} = 2 {m}_{H , i , j} {W}_{i , j} & ( 32 )\end{matrix}$$

An iterative estimation algorithm is as follows.

1. Set initial P(xᵢ, tⱼ) and H(xᵢ, tⱼ)
2. Update m_{P}(xᵢ, tⱼ) and m_{H}(xᵢ, tⱼ) at (3)
3. Update P(xᵢ, tⱼ) and H(xᵢ, tⱼ) at (8), (12)
4. End if converge, return to 2 if not

### [C-2-4] Utilization of Auxiliary Function for Squared Difference Term

According to the above-mentioned solution using I-divergence, a value of neighboring time-frequency bin is required for update equation of each P(x, t) and H(x, t). Here, the auxiliary function approach is applied to squared difference term of function of smoothness to solve the problem.

Generally,

(A−B)²≦2(A−C)²+2(B−C)² (33)

is satisfied. Equality is satisfied if

$$C = \frac{A + B}{2} \qquad ( 34 )$$

By using the formula, supremum function for smoothness constraint term can be given as

$$\begin{matrix}{Ω}_{P} \leq \frac{1}{2 {σ}_{P}^{2}} {\sum }_{i = 1}^{I - 1} {\sum }_{j = 1}^{J} 2 {( \sqrt{P ( {x}_{i + 1} , {t}_{j} )} - {C}_{i , j} )}^{2} + 2 {( \sqrt{P ( {x}_{i} , {t}_{j} )} - {C}_{i , j} )}^{2} = {Ω}_{P}^{+} & ( 35 ) \\ {Ω}_{H} \leq \frac{1}{2 {σ}_{H}^{2}} {\sum }_{i = 1}^{1} {\sum }_{j = 1}^{J - 1} 2 {( \sqrt{H ( {x}_{i} , {t}_{j + 1} )} - {D}_{i , j} )}^{2} + 2 {( \sqrt{H ( {x}_{i} , {t}_{j} )} - {D}_{i , j} )}^{2} = {Ω}_{H}^{+} & ( 36 )\end{matrix}$$

Therefore, supremum function of objective function can be obtained as

$${J}_{1} = \int \int W ( x , t ) log ( \frac{W ( x , t )}{P ( x , t ) + H ( x , t )} ) - ( W ( x , t ) - P ( x , t ) - H ( x , t ) ) + d x d t + {Ω}_{P} + {Ω}_{H} \leq \int \int m ( x , t ) W ( x , t ) log ( \frac{{m}_{P} ( x , t ) W ( x , t )}{P ( x , t )} ) + {m}_{H} ( x , t ) W ( x , t ) log ( \frac{{m}_{H} ( x , t ) W ( x , t )}{H ( x , t )} ) d x d t - \int \int W ( x , t ) - P ( x , t ) - H ( x , t ) d x d t + {Ω}_{P}^{+} + {Ω}_{H}^{+} = {J}_{S} \qquad ( 37 )$$

Update equations for P(x, t) and H(x, t) are obtained as follows:

$$\begin{matrix}\frac{\partial {J}_{a}}{\partial {P}_{i , j}} = \{ \begin{matrix}- \frac{{m}_{P , i , j} {W}_{i , j}}{{P}_{i , j}} + \frac{1}{{σ}_{P}^{2} \sqrt{{P}_{i , j}}} ( 2 \sqrt{{P}_{i , j}} - {C}_{i , j} - {C}_{i - 1 , j} ) + 1 & ( 2 \leq i \leq I - 1 ) \\ - \frac{{m}_{P , i , j} {W}_{i , j}}{{P}_{i , j}} + \frac{1}{{σ}_{P}^{2} \sqrt{{P}_{i , j}}} ( \sqrt{{P}_{i , j}} - {C}_{i , j} ) + 1 & ( i = 1 ) \\ - \frac{{m}_{P , i , j} {W}_{i , j}}{{P}_{i , j}} + \frac{1}{2 {σ}_{P}^{2} \sqrt{{P}_{i , j}}} ( \sqrt{{P}_{i , j}} - {C}_{i - 1 , j} ) + 1 & ( i = I )\end{matrix} & ( 38 ) \\ {\hat{P}}_{i , j} = {( \frac{{b}_{P , i , j} + \sqrt{{b}_{P , i , j}^{2} + 4 {a}_{P , i , j} {c}_{P , i , j}}}{2 {a}_{P , i , j}} )}^{2} & ( 39 ) \\ {a}_{P , i , j} = \{ \begin{matrix}\frac{2}{{σ}_{P}^{2}} + 1 & ( 2 \leq i \leq I - 1 ) \\ \frac{1}{{σ}_{P}^{2}} + 1 & ( otherwise )\end{matrix} & ( 40 ) \\ {b}_{P , i , j} = \{ \begin{matrix}\frac{{C}_{i , j} + {C}_{i - 1 , j}}{{σ}_{P}^{2}} & ( 2 \leq i \leq I - 1 ) \\ \frac{{C}_{i , j}}{{σ}_{P}^{2}} & ( i = 1 ) \\ \frac{{C}_{i - 1 , j}}{{σ}_{P}^{2}} & ( i = I )\end{matrix} & ( 41 ) \\ {C}_{P , i , j} = {m}_{P , i , j} {W}_{i , j} \\ & ( 42 ) \\ {\hat{H}}_{i , j} = {( \frac{{b}_{H , i , j} + \sqrt{{b}_{H , i , j}^{2} + 4 {a}_{H , i , j} {c}_{H , i , j}}}{2 {a}_{H , i , j}} )}^{2} & ( 43 ) \\ {a}_{H , i , j} = \{ \begin{matrix}\frac{2}{{σ}_{H}^{2}} + 1 & ( 2 \leq i \leq I - 1 ) \\ \frac{1}{{σ}_{P}^{2}} + 2 & ( otherwise )\end{matrix} & ( 44 ) \\ {b}_{H , i , j} = \{ \begin{matrix}\frac{{D}_{i , j} + {D}_{i , j - 1}}{{σ}_{H}^{2}} & ( 2 \leq j \leq J - 1 ) \\ \frac{{D}_{i , j}}{{σ}_{H}^{2}} & ( j = 1 ) \\ \frac{{D}_{i , j - 1}}{{σ}_{H}^{2}} & ( j = J )\end{matrix} & ( 45 ) \\ {C}_{H , i , j} = {m}_{H , i , j} {W}_{i , j} & ( 46 )\end{matrix}$$

Updates of M_{P,i,j}, M_{H,I,j}, C_{i,j} and D_{i,j} are as follows:

$$\begin{matrix}{m}_{P , i , j} = \frac{{P}_{i , j}}{{P}_{i , j} + Hi , j} & ( 47 ) \\ {m}_{H , i , j} = 1.0 - {m}_{P , i , j} & ( 48 ) \\ {C}_{i , j} = \frac{\sqrt{{P}_{i + 1 , j}} + \sqrt{{P}_{i , j}}}{2} & ( 49 ) \\ {D}_{i , j} = \frac{\sqrt{{H}_{i , j + 1}} + \sqrt{{P}_{i , j}}}{2} & ( 50 )\end{matrix}$$

An iterative estimation algorithm is as follows.

1. Set initial P(xᵢ, tⱼ) and H(xᵢ, tⱼ)
2. Update m_{P}(xᵢ, tⱼ), m_{H}(xᵢ, tⱼ), C_{i,j}, and D_{i,j}
3. Update P(xᵢ, tⱼ) and H(xᵢ, tⱼ) with the auxiliary function fixed
4. End if converge, return to 2 if not

### [C-2-5] Update of Variances of Smoothness Constraint

According to the above-defined cost function for smoothness, parameters σ_{P} and σ_{H} for determining strength of cost are regarded as a constant. Here, update equations are obtained for these parameters as variables.

By taking logarithms of the following prior distributions of P and H using Gaussian distribution

$${Π}_{i , j} \frac{1}{\sqrt{2 {πσ}_{P}}} {e}^{- \frac{{( \sqrt{{P}_{i + 1 , j}} - \sqrt{{P}_{i , j}} )}^{2}}{2 {σ}_{P}^{2}}} \frac{1}{\sqrt{2 π} {σ}_{H}} {e}^{- \frac{{( \sqrt{{H}_{i , j + 1}} - \sqrt{{H}_{i , j}} )}^{2}}{2 {σ}_{H}^{2}}} \qquad ( 51 )$$

and penalty for smoothness can be defined as follows:

$$\begin{matrix}{Ω}_{P} = \frac{1}{2 {σ}_{P}^{2}} {\sum }_{i = 1}^{I - 1} {\sum }_{j = 1}^{J} {( \sqrt{P ( {x}_{i + 1} , {t}_{j} )} - \sqrt{P ( {x}_{i} , {t}_{j} )} )}^{2} + log ( {σ}_{P} ) & ( 52 ) \\ {Ω}_{H} = \frac{1}{2 {σ}_{H}^{2}} {\sum }_{i = 1}^{I} {\sum }_{j = 1}^{J - 1} {( \sqrt{H ( {x}_{i} , {t}_{j + 1} )} - \sqrt{H ( {x}_{i} , {t}_{j} )} )}^{2} + log ( {σ}_{H} ) & ( 53 )\end{matrix}$$

In the objective function using this penalty for smoothness, update equations for parameters σ_{P} and σ_{H} are derived as follows:

$$\begin{matrix}\frac{\partial J}{\partial {σ}_{P}} = - \frac{1}{{σ}_{P}^{3}} {\sum }_{i = 1}^{I - 1} {\sum }_{j = 1}^{J} {( \sqrt{{P}_{i + 1 , j}} - \sqrt{{P}_{i , j}} )}^{2} + \frac{( I - 1 ) J}{{σ}_{P}} = 0 \\ {\hat{σ}}_{P}^{2} = \frac{{\sum }_{i = 1}^{I - 1} {\sum }_{j = 1}^{J} {( \sqrt{{P}_{i + 1 , j}} - \sqrt{{P}_{i , j}} )}^{2}}{( I - 1 ) J} & ( 54 ) \\ {\hat{σ}}_{H}^{2} = \frac{{\sum }_{i = 1}^{I} {\sum }_{j = 1}^{J - 1} {( \sqrt{{H}_{i , j + 1}} - \sqrt{{H}_{i , j}} )}^{2}}{I ( J - 1 )} & ( 55 )\end{matrix}$$

According to this model, update equations for P_{i,j} and H_{i,j} are the same as those in the previous section.

Different variances may be used depending on frequency. In this case, the penalty term can be defined as

$$\begin{matrix}{Ω}_{P} = \frac{1}{2 {σ}_{P , i}^{2}} {\sum }_{i = 1}^{I - 1} {\sum }_{j = 1}^{J} {( \sqrt{P ( {x}_{i + 1} , {t}_{j} )} - \sqrt{P ( {x}_{i} , {t}_{j} )} )}^{2} + log ( {σ}_{P} ) & ( 56 ) \\ {Ω}_{H} = \frac{1}{2 {σ}_{H , i}^{2}} {\sum }_{i = 1}^{I} {\sum }_{j = 1}^{J - 1} {( \sqrt{H ( {x}_{i} , {t}_{j + 1} )} - \sqrt{H ( {x}_{i} , {t}_{j} )} )}^{2} + log ( {σ}_{H} ) & ( 57 )\end{matrix}$$

In the objective function including the penalty term, update equations for parameters σ_{P . . . i,} and σ_{H,i,} are derived as follows:

$$\begin{matrix}\frac{\partial J}{\partial {σ}_{P , i}} = - \frac{1}{{σ}_{P}^{3}} {\sum }_{j = 1}^{J} {( \sqrt{{P}_{i + 1 , j}} - \sqrt{{P}_{i , j}} )}^{2} + \frac{J}{{σ}_{P}} = 0 \\ {\hat{σ}}_{P , i}^{2} = \frac{ {\sum }_{j = 1}^{J} {( \sqrt{{P}_{i + 1 , j}} - \sqrt{{P}_{i , j}} )}^{2}}{J} & ( 58 ) \\ {\hat{σ}}_{H , i}^{2} = \frac{ {\sum }_{j = 1}^{J - 1} {( \sqrt{{H}_{i , j + 1}} - \sqrt{{H}_{i , j}} )}^{2}}{J - 1} & ( 59 )\end{matrix}$$

Regarding this variance, update equation for only P_{i,j} is changed.

$$\begin{matrix}{\hat{P}}_{i , j} = {( \frac{{b}_{P , i , j} + \sqrt{{b}_{P , i , j}^{2} + 4 {a}_{P , i , j} {c}_{P , i , j}}}{2 {a}_{P , i , j}} )}^{2} & ( 60 ) \\ {a}_{P , i , j} = \{ \begin{matrix}\frac{1}{{σ}_{P , i}^{2}} + \frac{1}{{σ}_{P , i - 1}^{2}} + 2 & ( 2 \leq i \leq I - 1 ) \\ \frac{1}{{σ}_{P , i}^{2}} + 2 & ( i = 1 ) \\ \frac{1}{{σ}_{P , i - 1}^{2}} + 2 & ( i = I )\end{matrix} & ( 61 ) \\ {b}_{P , i , j} = \{ \begin{matrix}\frac{\sqrt{{P}_{i - 1 , j}}}{{σ}_{P , i - 1}^{2}} + \frac{\sqrt{{P}_{i + 1 , j}}}{{σ}_{P , i}^{2}} & ( 2 \leq i \leq I - 1 ) \\ \frac{\sqrt{{P}_{i + 1 , j}}}{{σ}_{P , i}^{2}} & ( i = 1 ) \\ \frac{\sqrt{{P}_{i - 1 , j}}}{{σ}_{P , i - 1}^{2}} & ( i = I )\end{matrix} & ( 62 ) \\ {C}_{P , i , j} = 2 {m}_{P , i , j} {W}_{i , j} & ( 63 )\end{matrix}$$

### [C-2-6] Introduction of Sparseness

In addition to smoothness constraint, it is possible to introduce sparse constraint in which zero is assigned to magnitude of P_{i,j} and H_{i,j} as many as possible. The sparse constraint may facilitate comfortable hearing of separated signal. The preceding embodiment refers to binarization as post-processing but here binarization is conducted during an iterative estimation by introducing the term.

Sparse constraint can be obtained by adding the following term to the objective function assuming Laplace distribution.

$${χ}_{P} {\sum }_{i , j} \sqrt{{P}_{i , j}} + {χ}_{H} {\sum }_{i , j} \sqrt{{H}_{i , j}} \qquad ( 64 )$$

The following term may also be used.

$${χ}_{P} {\sum }_{i , j} log {P}_{i , j} + {χ}_{H} {\sum }_{i , j} log {H}_{i , j} \qquad ( 65 )$$

In the former case, update equations for P_{i,j} and H_{i,j} are the followings.

$$\begin{matrix}{\hat{P}}_{i , j} = {( \frac{{b}_{P , i , j} + \sqrt{{b}_{P , i , j}^{2} + 4 {a}_{P , i , j} {c}_{P , i , j}}}{2 {a}_{P , i , j}} )}^{2} & ( 66 ) \\ {a}_{P , i , j} = \{ \begin{matrix}\frac{2}{{σ}_{P}^{2}} + 2 & ( 2 \leq i \leq I - 1 ) \\ \frac{1}{{σ}_{P}^{2}} + 2 & ( otherwise )\end{matrix} & ( 67 ) \\ {b}_{P , i , j} = \{ \begin{matrix}\frac{( \sqrt{P \text{?}} + \sqrt{P \text{?}} )}{{σ}_{P}^{2}} - {χ}_{P} & ( 2 \leq i \leq I - 1 ) \\ \frac{\sqrt{P \text{?}}}{{σ}_{P}^{2}} - {χ}_{P} & ( i = 1 ) \\ \frac{\sqrt{P \text{?}}}{{σ}_{P}^{2}} - {χ}_{P} & ( i = I )\end{matrix} & ( 68 ) \\ {c}_{P , i , j} = 2 {m}_{P , i , j} {W}_{i , j} & ( 69 ) \\ {\hat{H}}_{i , j} = {( \frac{{b}_{H , i , j} + \sqrt{{b}_{H , i , j}^{2} + 4 {a}_{H , i , j} {c}_{H , i , j}}}{2 {a}_{H , i , j}} )}^{2} & ( 70 ) \\ {a}_{H , i , j} = \{ \begin{matrix}\frac{2}{{σ}_{H}^{2}} + 2 & ( 2 \leq i \leq I - 1 ) \\ \frac{1}{{σ}_{H}^{2}} + 2 & ( otherwise )\end{matrix} & ( 71 ) \\ {b}_{H , i , j} = \{ \begin{matrix}\frac{( \sqrt{H \text{?}} + \sqrt{H \text{?}} )}{{σ}_{H}^{2}} - {χ}_{H} & ( 2 \leq j \leq J - 1 ) \\ \frac{\sqrt{H \text{?}}}{{σ}_{H}^{2}} - {χ}_{H} & ( j = 1 ) \\ \frac{\sqrt{H \text{?}}}{{σ}_{H}^{2}} - {χ}_{H} & ( j = J )\end{matrix} & ( 72 ) \\ {c}_{H , i , j} = 2 {m}_{H , i , j} {W}_{i , j} \\ \text{?} \text{indicates text missing or illegible when filed} & ( 73 )\end{matrix}$$

Iterative update can be conducted using these equations.

According to the proposed iterative estimation, values of time-frequency masks m_{P}(x, t) and m_{H}(x, t) are estimated as a continuous value between 0 and 1. However, considering that the harmonic component and percussive component occur on the time-frequency plane sparsely and that the binary mask facilitates performance of separation in actual hearing, it may be effective to modify the estimated masks having a continuous value to the binary masks. The binary mask can be designed based on the relation (greater or smaller) between estimated m_{P}(x, t) and m_{H}(x, t).

$${\overline{m}}_{P} ( x , t ) = \{ \begin{matrix}1 & ( if {m}_{P} ( x , t ) > {m}_{H} ( x , t ) ) \\ 0 & ( otherwise )\end{matrix} \\ {\overline{m}}_{H} ( x , t ) = 1 - {\overline{m}}_{P} ( x , t )$$

However, when designing complete binary masks, discontinuousness of spectral elements in the time and frequency directions may result in uncomfortable hearing of separated sound. Here, the masks can be designed by using a parameter γ that represents strength of binarizing.

$${\overline{m}}_{P} ( x , t ) = \frac{{{m}_{P} ( x , t )}^{γ}}{{{m}_{P} ( x , t )}^{γ} + {{m}_{H} ( x , t )}^{γ}}$$

$${\overline{m}}_{H} ( x , t ) = \frac{{{m}_{H} ( x , t )}^{γ}}{{{m}_{P} ( x , t )}^{γ} + {{m}_{H} ( x , t )}^{γ}}$$

With a larger y, the mask becomes closer to the binary mask, and becomes the complete binary mask if γ→∞. If γ=1, the mask corresponds with the original mask having a continuous value.

### [C-3] Real-Time Separation System

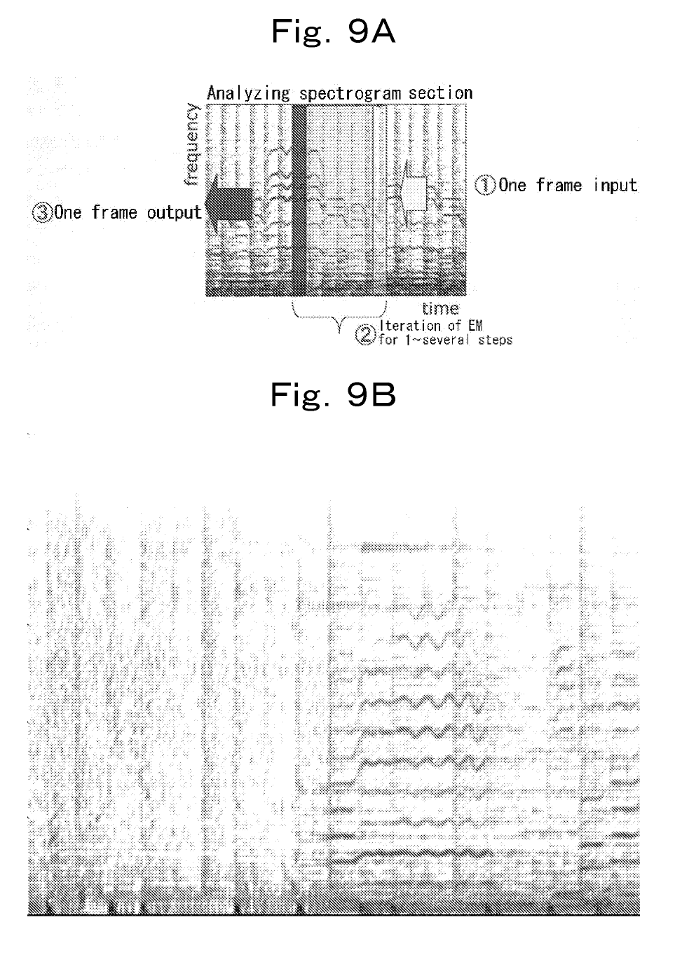

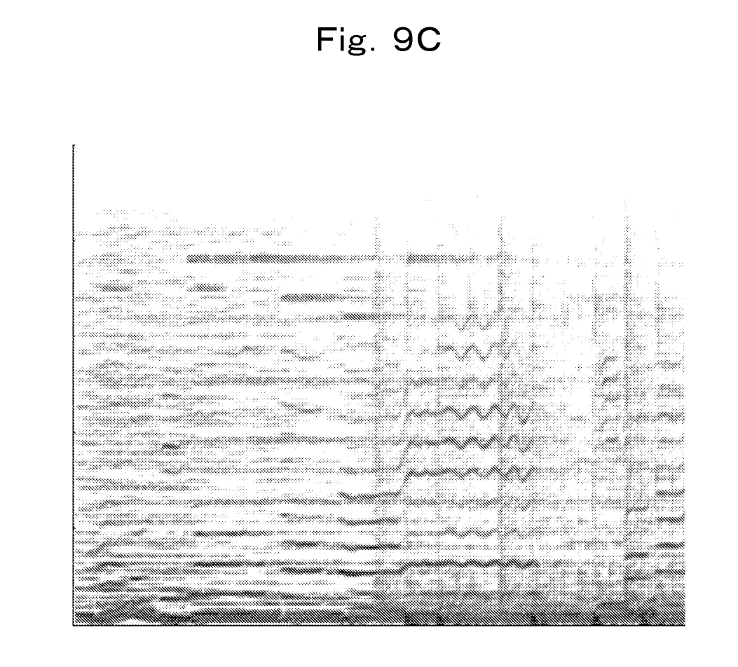

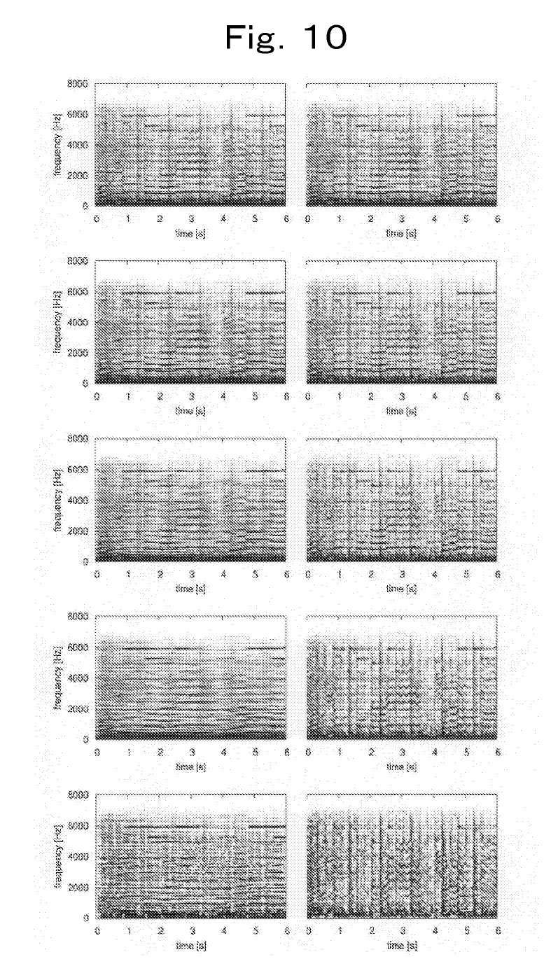

In general, a real-time separation is not easy because the above solution is an iterative solution of whole input signal in the time frequency domain. However, if the smoothness of spectrogram is represented by a differential cost using only adjacent time frequency bins, an appropriate solution may be obtained with a local analyzing section. Here, by using a local analyzing section, by alternately performing the shift of analyzing section and iterative update of parameters (1˜several times), the real-time harmonic/percussion sounds separation system is realized (FIG. 9A). Steps for the real-time harmonic/percussion sounds separation are as follows:

1. Obtain an input spectrogram of an initial analyzing section.
2. Obtain another input spectrogram of one frame and add the one-frame spectrogram to the analyzing section.
3. Iteratively update separated spectrogram and time-frequency masks for 1˜several times using the spectrogram of the analyzing section.
4. Separate the spectrogram of the oldest frame in the analyzing section by an estimated time-frequency mask and output the separated signal by inverse Fourier transform.
5. End if the music is over. Otherwise, go to step 2.

### [C-4] Experimental Evaluations

[C-4-1] Application to Actual Music Quantitative experiments using signals of performed popular song music are described. An input signal was chosen from RWC Music Database and RWCMDB-P-2001 No. 7 was used (sampling: 16 kHz). A spectrogram of the input signal, separation results by the proposed algorithm are shown in FIG. 8.

It is noted from the result that P(x, t) and H(x, t) are separated in a manner that satisfies the focused characteristics of P(x, t) and H(x, t). In auditory evaluation of the resultant sound, the signal is well separated and the more comfortable hearing is obtained especially for the harmonic sound in comparison with the method of the first embodiment. However, similar to the first embodiment, it is confirmed that duration of high-hat and bass drum was separated into H(x, t) and vibrato and consonant of voice tend to be separated into P(x, t).

### [C-4-2] Quantitative Evaluation Experiments Regarding Separation of Each Part

Quantitative evaluation experiments using an each part signal were conducted. As an input signal, the prelude of RWC-MDB-P-2001 No. 18 for 8.1 seconds was used. MIDI formatted data was separated into each part and each part was converted to WAV format and then summation of these signals was used as an input (sampling: 16 kHz). Energy ratios included in P(x, t) and H(x, t) are obtained by calculating cross-correlation between the separated signal by the first/second embodiments and individual part signal and compared together with computational time (Table 2, computed by machine with CPU 3.6 GHz). As shown in table 2, the method of the second embodiment can improve separation performance while requiring a more computational cost in comparison with the method of the first embodiment. According to the both method, bass drum was separated as harmonic sound.

TABLE 2
THE ENERGY RATIO OF EACH INSTRUMENTAL PART

| 1st embodiment | 2nd embodiment |
|---|---|
| Computational time | |
| 0.31[s] | 2.52[s] |

| Part | P ratio | H ratio | P ratio | H ratio |
|---|---|---|---|---|
| piano | 0.239 | 0.761 | 0.071 | 0.929 |
| bass | 0.352 | 0.648 | 0.063 | 0.957 |
| synthesizer | 0.259 | 0.741 | 0.029 | 0.971 |
| electric guitar | 0.233 | 0.767 | 0.074 | 0.926 |
| melody | 0.142 | 0.858 | 0.122 | 0.878 |
| brass | 0.363 | 0.637 | 0.373 | 0.627 |
| snare drum | 0.892 | 0.108 | 0.939 | 0.061 |
| high-hat | 0.923 | 0.077 | 0.972 | 0.028 |
| bass drum | 0.093 | 0.907 | 0.019 | 0.981 |

As foregoing, the second embodiment can provide the solution based on the anisotropy of smoothness on the spectrogram which enables the separation similar to that of the first embodiment solution and provides higher and faster separation performance which is sufficient for the real-time separation. The solution is based on the simple characteristics without using the knowledge of music instruments and a relatively tone of bass drum and high-hat, piano sound, and voice having variable pitches may not meet the characteristics so that the solution may not correspond to the conventional classification of music instruments. However, the real-time separation is a great advantage of the embodiment.

### [D] Third Embodiment

According to the second embodiment, H(x, t) and P(x, t) are estimated from W(x, t). According to the third embodiment, smoothness cost of distributed spectrogram is minimized without using H(x, t) and P(x, t).

### [D-1] Prior Models of Harmonic/Percussive Components

Let F_{h,i} be a Short-Time Fourier Transform (STFT) of a monaural audio signal f(t), and W_{h,i}=φ(|F_{h,i}|²), where h and i represent indices of frequency and time bins. W_{h,i} is an usual spectrogram when φ(A)=A, and setting a convex function as φ(A) like φ(A)=A^{γ} (γ<1) yields a range compressed version of the spectrogram.

A harmonic component on the spectrogram usually has a stable pitch and form parallel ridges with smooth temporal envelopes, while the energy of a percussive tone is concentrated in a short time, which forms a vertical ridge with wideband spectral envelopes. Then typically, the vertical and horizontal structure emerges on the spectrogram of audio signals shown in FIG. 1. Since the intersection of the horizontal and vertical ridges is small. Then, the purpose here is finding an appropriate time-frequency binary mask m_{h,i} such that

H_{h,i}=m_{h,i}W_{h,i}, (1)

P_{h,i}=(1−m_{h,i})W_{h,i}, (2)

where H_{h,i} and P_{h,i} represent the harmonic and non-harmonic (percussive) components of spectrogram, respectively. One way to design the mask m_{h,i} is applying Maximum A Posteriori (MAP) estimation based on some prior distribution. Focusing on the horizontal and vertical smoothed envelope of H_{h,i} and P_{h,i} we assume the following a priori distribution for each component:

$$\begin{matrix}{p}_{H} ( H ) ∝ {\prod }_{h , i} \frac{1}{\sqrt{2 π} {σ}_{H}} exp ( - \frac{{( {H}_{h , i - 1} - {H}_{h , i} )}^{2}}{2 {σ}_{H}^{2}} ) , & ( 3 ) \\ {p}_{P} ( P ) ∝ {\prod }_{h , i} \frac{1}{\sqrt{2 π} {σ}_{P}} exp ( - \frac{{( {P}_{h - 1 , i} - {P}_{h , i} )}^{2}}{2 {σ}_{P}^{2}} ) , & ( 4 )\end{matrix}$$

where H and P represent sets of H_{i,j} and P_{i,j}, respectively, and σ²_{H} and σ²_{P} are variance of the spectrogram gradients, which probably depends on the frame length or frame shift of STFT. Although the actual distribution of spectrogram gradients is different from the Gaussian distribution, the assumption leads us to simple and comprehensive formulation and solution. As confirmed later, compressing the dynamic range of the spectrogram with φ(A) partially bridges a gap between the assumption and the real situation.

Thus, the objective function of MAP estimation here can be written as

$$J ( m ) = - \frac{1}{2 {σ}_{H}^{2}} {\sum }_{h , i} {( {m}_{h , i - 1} {W}_{h , i - 1} - {m}_{h , i} {W}_{h , i} )}^{2} - \frac{1}{2 {σ}_{P}^{2}} {\sum }_{h , i} {( ( 1 - {m}_{h - 1 , i} ) {W}_{h - 1 , i} - ( 1 - {m}_{h , i} ) {W}_{h , i} )}^{2} , \qquad ( 5 )$$

where m is a set of m_{i,j} and constant terms are omitted for simplicity.

### [D-2] Derivation of Update Rules Through Auxiliary Function

Since eq. (5) is a quadrature form of m_{h,i}, the optimal m is obtained by solving δJ/δm_{h,i}=0, if we handle m_{i,j} as a continuous-valued variable. Here, to solve δJ/δm_{h,i}=0 easily, we adopt an auxiliary function approach, which is known and used in NMF(Non-negative matrix factorization) or HTC(Harmonic-Temporal Clustering).

In order to design the auxiliary function of our problem, note that

(A−B)²≦2(A−X)²+2(B−X)² (6)

for any A, B, and X since

$$2 {( A - X )}^{2} + 2 {( B - X )}^{2} - {( A - B )}^{2} = 4 {( X - \frac{A + B}{2} )}^{2} \qquad ( 7 )$$

is obviously nonnegative and equal to zero where X=(A+B)=2. Applying the inequality to eq. (5), we introduce the following auxiliary function:

$$Q ( m , U , V ) = - \frac{1}{{σ}_{H}^{2}} {\sum }_{h , i} {( {m}_{h , i - 1} {W}_{h , i - 1} - {U}_{h , i} )}^{2} - \frac{1}{{σ}_{H}^{2}} {\sum }_{h , i} {( {m}_{h , i} {W}_{h , i} - {U}_{h , i} )}^{2} - \frac{1}{{σ}_{P}^{2}} {\sum }_{h , i} {( ( 1 - {m}_{h - 1 , i} ) {W}_{h - 1 , i} - {V}_{h , i} )}^{2} - \frac{1}{{σ}_{P}^{2}} {\sum }_{h , i} {( ( 1 - {m}_{h , i} ) {W}_{h , i} - {V}_{h , i} )}^{2} , \qquad ( 8 )$$

which satisfies

$$\begin{matrix}J ( m ) \geq Q ( m , U , V ) , & ( 9 ) \\ J ( m ) = {max}_{U , V} Q ( m , U , V ) , & ( 10 )\end{matrix}$$

for any m and auxiliary parameters U, V.

Then, the following updates:

$$\begin{matrix}\{ {U}^{( k + 1 )} , {V}^{( k + 1 )} \} = {max}_{U , V} Q ( {m}^{( k )} , U , V ) , & ( 11 ) \\ {m}^{( k + 1 )} = {max}_{m} Q ( m , {U}^{( k + 1 )} , {V}^{( k + 1 )} ) , & ( 12 )\end{matrix}$$

increase J monotonically, where k represents the number of iterations.

### [D-3] Update Rules

Since δQ(m, U^{(k+1)}, V^{(k+1)})/δm_{h,i}=0 can be deformed to

$${m}_{h , i} {W}_{h , i} = ( \begin{matrix}\frac{{U}_{h , i}^{( k + 1 )} + {U}_{h , i + 1}^{( k + 1 )}}{{σ}_{H}^{2}} + \\ \frac{2 {W}_{h , i} - {V}_{h + 1 , i}^{( k + 1 )} - {V}_{h , i}^{( k + 1 )}}{{σ}_{P}^{2}}\end{matrix} ) / 2 ( \frac{1}{{σ}_{H}^{2}} + \frac{1}{{σ}_{P}^{2}} ) , \qquad ( 13 )$$

which is the equation of only m_{h,i} it yields a simple update equation. While, from eq. (7), U_{h,i} and V_{h,i} maximizing Q(m^{(k)}, U, V) are given by

$$\begin{matrix}{U}_{h , i} = \frac{{m}_{h , i - 1}^{( k )} {W}_{h , i - 1} + {m}_{h , i}^{( k )} {W}_{h , i}}{2} , & ( 14 ) \\ {V}_{h , i} = \frac{( 1 - {m}_{h - 1 , i}^{( k )} ) {W}_{h - 1 , i} + ( 1 - {m}_{h , i}^{( k )} ) {W}_{h , i}}{2} . & ( 15 )\end{matrix}$$

Substituting eq. (14) and eq. (15) into eq. (13), and taking H_{h,i} and P_{h,i} as update variables instead of m_{h,i} the separation algorithm is consequently summarized as follows.

1) Calculate F_{h,i}, the STFT of an input signal f(t).
2) Calculate a range-compressed version of the power spectrogram by

W_{h,i}=φ(|F_{h,i}|²). (16)

3) Set initial values to the parameters as

$${H}_{h , i}^{( 0 )} = {P}_{h , i}^{( 0 )} = \frac{1}{2} {W}_{h , i} , \qquad ( 17 )$$

for all h and i and set k=0.
4) Calculate the update variables Δ^{(k)} as

$$\begin{matrix}{Δ}^{( k )} = α ( \frac{\begin{matrix}{H}_{1 , i - 1}^{( k )} - 2 {H}_{h , i}^{( k )} + \\ {H}_{h , i - 1}^{( k )}\end{matrix}}{4} ) - ( 1 - α ) ( \frac{\begin{matrix}{P}_{h - 1 , i}^{( k )} - 2 {P}_{h , i}^{( k )} + \\ {P}_{h + 1 , i}^{( k )}\end{matrix}}{4} ) , \\ where & ( 18 ) \\ α = \frac{{σ}_{P}^{2}}{{σ}_{H}^{2} + {σ}_{P}^{2}} . & ( 19 )\end{matrix}$$

Then, update H_{h,i} and P_{h,i} according to cases as follows.

i) H_{h,i}^{(k)}−Δ^{(k)}≧0 and P_{h,i}^{(k)}+Δ^{(k)}≧0:

H_{h,i}^{(k+1)}=H_{h,i}^{(k)}−Δ^{(k)}, (20)

P_{h,i}^{(k+1)}=P_{h,i}^{(k)}+Δ^{(k)}. (21)

ii) H_{h,i}^{(k)}−Δ^{(k)}<0:

H_{h,i}^{(k+1)}=0, P_{h,i}^{(k+1)}=W_{h,i}. (22)

iii) P_{h,i}^{k}+Δ^{(k)}<0:

H_{h,i}^{(k+1)}=W_{h,i}, P_{h,i}^{(k+1)}=0. (23)

5) Increment k. If k<kₘₐₓ(kₘₐₓ is the maximum number of iterations), then, go to step 4), else, go to step 6).
6) Binarize the designed mask. It is equivalent to the following.

H_{h,i}^{(k}^{ₘₐₓ}⁻¹⁾<P_{h,i}^{(k}^{ₘₐₓ}⁻¹⁾:

H_{h,i}^{(k}^{ₘₐₓ}⁾=0, P_{h,i}^{(k}^{ₘₐₓ}⁾=W_{h,i}. (24)

ii) P_{h,i}^{(k}^{ₘₐₓ}⁻¹⁾≦H_{h,i}^{(k}^{ₘₐₓ}⁻¹⁾:

H_{h,i}^{(k}^{ₘₐₓ}⁾=W_{h,i}. P_{h,i}^{(k}^{ₘₐₓ}⁾=0. (25)

7) Convert H^{(kmax)}_{h,i} and P^{(kmax)}_{h,i} into the waveform in time domain by

h(t)=ISTFT[φ⁻¹(\sqrt{H_{h,i}^{(k}^{ₘₐₓ}⁾})e^{j∠F}^{_{h,i}}], (26)

p(t)=ISTFT[φ⁻¹(\sqrt{P_{h,i}^{(k}^{ₘₐₓ}⁾})e^{j∠F}^{_{h,i}}], (27)

where ISTFT represents the inverse STFT.

### [D-4] Experimental Evaluations

Several experiments were conducted according to the third embodiment. The target signals were chosen from the RWC Music Database (Popular Music Database) and the sampling frequency was 16[kHz]. The parameters we used in the experiment are shown in Table 3. The balance parameter α and the compress parameter γ were determined experimentally.

TABLE 3
EXPERIMENTAL CONDITIONS

| | | |
|---|---|---|
| signal length | 6.25 | s |
| sampling rate | 16 | kHz |

| | |
|---|---|
| frame size of FFT | 1024 |
| frame shift | 512 |
| balance parameter | α = 0.3 |
| compress function | φ(A) = A^{γ} |
| compress parameter | γ = 0.3, 1.0 |
| maximum number of iterations | kₘₐₓ = 50 |

The resultant spectrograms of the harmonic component H^{(kmax)}_{h,i} and the percussive component P^{(kmax)}_{h,i} to 6.25[s] fragment of RWCMDB-P-2001 No. 7 is shown in FIG. 2, where γ=0:3 was used. We can see that the energy of spectrogram is splitting to two components as iterations, each of which substantially consists of horizontal and vertical ridges, respectively. The computational time for a 6.25[s]-length signal with 50 iterations is about 2.3[s] at a laptop-PC with 1.20 GHz Pentium in our implement, which is nearly three times faster than real-time processing.

In order to quantitatively evaluate how each part is separated by our algorithm, we separated each part of two MIDI formatted data (RWC-MDB-P-2001 No. 18 and RWC-MDBJ-2001 No. 16) and converted them to WAV format, and inputted the summation of all part to our algorithm. Then, the energy ratio of each part included in P(x, t) and H(x, t) was calculated as

$${r}_{h} = \frac{{E}_{h}}{{E}_{h} + {E}_{p}} , {r}_{p} = \frac{{E}_{p}}{{E}_{h} + {E}_{p}} , \qquad ( 28 )$$

where

Eₕ=<fᵢ(t),h(t)>², (29)

Eₚ=<fᵢ(t),p(t)>², (30)

and < > represents the cross-correlation operation. The results are shown in Tables 4 and 5.

TABLE 4
THE ENERGY RATIO OF EACH INSTRUMENTAL PART

| | |
|---|---|
| γ = 0.3 | γ = 1.0 |

| instrument | H | P | H | P |
|---|---|---|---|---|
| piano | 0.877 | 0.123 | 0.942 | 0.058 |
| bass | 0.927 | 0.073 | 0.840 | 0.160 |
| synthesizer | 0.962 | 0.038 | 0.941 | 0.059 |
| bell | 0.942 | 0.058 | 0.941 | 0.059 |
| snare drum | 0.139 | 0.861 | 0.389 | 0.611 |
| bass drum | 0.918 | 0.082 | 0.565 | 0.435 |
| high-hat | 0.038 | 0.962 | 0.281 | 0.719 |
| melody | 0.706 | 0.294 | 0.777 | 0.223 |
| brass | 0.681 | 0.319 | 0.764 | 0.236 |

TABLE 5
THE ENERGY RATIO OF EACH INSTRUMENTAL PART

| | |
|---|---|
| γ = 0.3 | γ = 1.0 |

| instrument | H | P | H | P |
|---|---|---|---|---|
| piano | 0.951 | 0.049 | 0.964 | 0.036 |
| bass | 0.901 | 0.099 | 0.770 | 0.230 |
| snare drum | 0.041 | 0.959 | 0.281 | 0.719 |
| high-hat 1 | 0.037 | 0.963 | 0.189 | 0.811 |
| high-hat 2 | 0.003 | 0.997 | 0.059 | 0.941 |
| bass drum | 0.001 | 0.999 | 0.001 | 0.999 |

### INDUSTRIAL APPLICABILITY

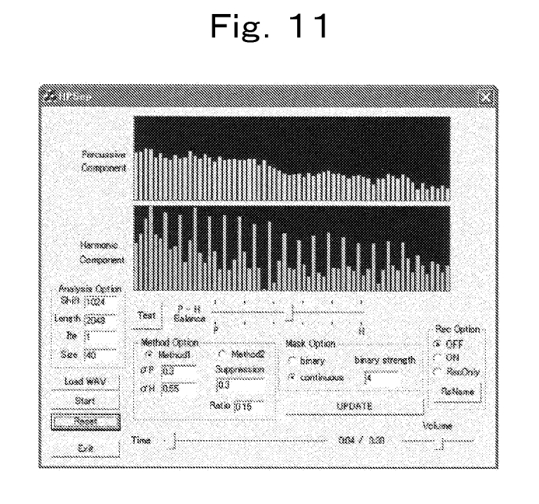

The present invention relates to the technique that separates the music signal into the harmonic component and percussive component without the information regarding music instruments and scores. This technique is useful as a basic technique that facilitates various tasks in analyzing the music signal including music information retrieval and automatic music transcription and in modifying the music signal such as equalizing including emphasizing or suppressing melody/rhythm part. In this regard, FIG. 11 shows a GUI screen of real-time harmonic sound/percussion sound separation system. This system comprises displaying power spectrum of separated harmonic sound and percussion sound at real-time and modification function for reproducing music by adjusting volume balance of harmonic sound and percussion sound. An audio signal to be processed by the invention is not limited to the music signal but the present invention may be applicable to detection of an irregular sound from an industrial sound generated from machinery or device.

1. A method of separating an acoustic signal wherein a spectrogram of the acoustic signal is assumed to be a sum of a plurality of sub-spectrograms, and smoothness of spectral elements of each sub-spectrogram in a time-frequency domain has directionality on a time-frequency plane,
obtaining a distribution coefficient for distributing spectral elements of said acoustic signal in the time-frequency domain to at least one sub-spectrogram based on the directionality of the smoothness of each sub-spectrogram on the time-frequency plane, and
separating at least one sub-spectrogram from said spectral elements of said acoustic signal using said distribution coefficient.

2. The method of claim 1 wherein said distribution coefficient is a time-frequency mask.

3. The method of claim 1, said obtaining a distribution coefficient comprising:
obtaining a likelihood score as a spectral element of each sub-spectrogram based on the directionality of the smoothness of each sub-spectrogram regarding with respect to each spectral element of said acoustic signal, and
obtaining the distribution coefficient by using said likelihood score as an index.

4. The method of claim 3, said obtaining a likelihood score comprising:
providing filters for extracting characteristics of spectral elements belonging to each sub-spectrogram from said spectrogram of said acoustic signal assuming that said spectrogram of said acoustic signal is an image on the time-frequency plane having values corresponding to energy of each spectral element, and
obtaining outputs processed by said filters corresponding to each sub-spectrogram with respect to each spectral element as said score.

5. The method of claim 4, wherein said filter is a low-pass filter for smoothing the values of spectral elements of each sub-spectrogram along the direction of smoothness of spectral elements.

6. The method of claim 3, wherein said spectrogram of said acoustic signal is assumed to be the sum of two sub-spectrograms, the method comprising:
comparing said scores to obtain a higher score and a lower score; and
assigning the distribution coefficient of value 1 to the spectral element having a higher score and the distribution coefficient of value 0 to the spectral element having a lower score.

7. The method of claim 1, said obtaining a distribution coefficient comprising:
providing an objective function comprising a function of smoothness index of each spectral element distributed to each sub-spectrogram based on the distribution coefficient as parameters, and
estimating said parameters for optimizing said objective function.

8. The method of claim 7 wherein said smoothness index of each distributed spectral element is determined by energy difference between a spectral element of interest and neighboring spectral elements on said time-frequency plane.

9. The method of claim 8, wherein said function of smoothness index is
$${\sum }_{k} {\sum }_{i , j} {f}_{k} ( {\sum }_{m , n} {a}_{m , n}^{( k )} g ( {Q}_{i - m , j - n}^{( k )} ) )$$
where
K: the number of sub-spectrograms;
i: index in the frequency direction;
j: index in the temporal direction;
f_{K}(x): cost function for measuring smoothness;
a_{m,n}: weighting coefficients for neighborhood of a point of interest in the time-frequency domain;
m: index for neighborhood in the frequency direction;
n: index for neighborhood in the temporal direction;
g(x): range-compressed function for spectrogram regarding smoothness index; and
Q^{(K)}_{i,j}: spectral elements of sub-spectrogram.

10. The method of claim 7, wherein said objective function comprises a function of distance index between the spectral elements of said acoustic signal and the sum of each spectral element distributed by said distribution coefficient as a parameter.

11. The method of claim 7, wherein said spectrogram of said acoustic signal is assumed to be the sum of K sub-spectrograms, and said objective function is
$$J = {\sum }_{i , j} D ( φ ( {W}_{i , j} ) , {\sum }_{k} φ ( {Q}_{i , j}^{( k )} ) ) + {\sum }_{k} {\sum }_{i , j} {f}_{k} ( {\sum }_{m , n} {a}_{m , n}^{( k )} g ( {Q}_{i - m , j - n}^{( k )} ) )$$
where
K: the number of sub-spectrograms;
i: index for frequency direction;
j: index for temporal direction;
D(A, B): distance index between function A and function B;
φ(x): range-compressed function for spectrogram regarding distance index;
W_{i,j}: observed spectral elements;
f_{K}(x): cost function for measuring smoothness;
a_{m,n}: weighting coefficients for neighborhood of a point of interest in the time-frequency domain;
m: index for neighborhood in the frequency direction;
n: index for neighborhood in the temporal direction;
g(x): range-compressed function for spectrogram regarding smoothness index; and
Q^{(K)}_{i,j}: spectral elements of sub-spectrogram.

12. The method of claim 11, wherein said objective function comprises the following terms.
$$K = 2$$
$${Q}_{i , j}^{( 1 )} = {P}_{i , j}$$
$${Q}_{i , j}^{( 2 )} = {H}_{i , j}$$
$${f}_{1} ( x ) = \frac{1}{2 {σ}_{P}^{2}} {x}^{2}$$
$${f}_{2} ( x ) = \frac{1}{2 {σ}_{H}^{2}} {x}^{2}$$
$${a}_{m , n}^{( 1 )} = \{ \begin{matrix}- 1 & ( m = 0 , n = 0 ) \\ 1 & ( m = - 1 , n = 0 ) \\ 0 & ( ohterwise )\end{matrix} \\ {a}_{m , n}^{( 2 )} = \{ \begin{matrix}- 1 & ( m = 0 , n = 0 ) \\ 1 & ( m = 0 , n = - 1 ) \\ 0 & ( ohterwise )\end{matrix}$$

13. The method of claim 12, wherein said objective function comprises the following terms.
$$D ( A , B ) = A log \frac{A}{B} - A + B$$
$$φ ( x ) = x$$
$$g ( x ) = {x}^{0.5}$$

14. The method of claim 12, wherein said objective function comprises the following terms.
$$D ( A , B ) = \{ \begin{matrix}0 & ( A = B ) \\ ∞ & ( A \neq B )\end{matrix} \\ φ ( x ) = {x}^{γ} ( 0 < γ \leq 1 ) \\ g ( x ) = φ ( x )$$

15. The method of claim 7, said estimating the parameters comprising:
alternately iterating update of parameters and update of spectral elements corresponding to each sub-spectrogram distributed by the parameters.

16. The method of claim 7, wherein said spectrogram of said acoustic signal is assumed to be the sum of two sub-spectrograms, and
a function of energy difference between spectral elements that are adjacent in the time-frequency domain and distributed by the parameters is as follows:
$${Ω}_{P} = \frac{1}{2 {σ}_{P}^{2}} {\sum }_{i = 1}^{I - 1} {\sum }_{j = 1}^{J} {( \sqrt{{P}_{i + 1 , j}} - \sqrt{{P}_{i , j}} )}^{2}$$
$${Ω}_{H} = \frac{1}{2 {σ}_{H}^{2}} {\sum }_{i = 1}^{I} {\sum }_{j = 1}^{J - 1} {( \sqrt{{H}_{i , j + 1}} - \sqrt{{H}_{i , j}} )}^{2}$$

17. The method of claim 7 wherein said spectrogram of said acoustic signal is assumed to be the sum of two sub-spectrograms, and
said objective function is as follows:
$$J = {\sum }_{i , j} {m}_{P , i , j} {W}_{i , j} log ( \frac{{m}_{P , i , j} {W}_{i , j}}{{P}_{i , j}} ) + {\sum }_{i , j} {m}_{H , i , j} {W}_{i , j} log ( \frac{{m}_{H , i , j} {W}_{i , j}}{{H}_{i , j}} ) - {\sum }_{i , j} ( {W}_{i , j} - {P}_{i , j} - {H}_{i , j} ) + {Ω}_{P} + {Ω}_{H}$$

18. The method of claim 7 wherein said spectrogram of said acoustic signal is assumed to be the sum of two sub-spectrograms, and
said objective function is as follows:
$$J ( m ) = - \frac{1}{2 {σ}_{H}^{2}} {\sum }_{h , i} {( {m}_{h , i - 1} {W}_{h , i - 1} - {m}_{h , i} {W}_{h , i} )}^{2} - \frac{1}{2 {σ}_{P}^{2}} {\sum }_{h , i} {( ( 1 - {m}_{h - 1 , i} ) {W}_{h - 1 , i} - ( 1 - {m}_{h , i} ) {W}_{h , i} )}^{2} ,$$

19. The method of claim 7, said method further comprising:
obtaining spectral elements by transforming said acoustic signal in an initial analyzing section into the time-frequency domain;
transforming said acoustic signal in at least one frame into the time-frequency domain to obtain spectrum elements thereof and adding said spectrum elements of said at least one frame to said initial analyzing section;
estimating parameters using spectral elements of said analyzing section,
separating at least an oldest frame in said analyzing section by using the estimated parameter; and
transforming said separated spectral elements into the time domain.

20. The method of claim 7, further comprising binarizing said estimated distribution coefficient.

21. The method of claim 20, wherein strength of binarization is variable.

22. The method of claim 1, wherein at least one of said sub-spectrograms is either a sub-spectrogram having smoothness along the frequency direction or a sub-spectrogram having smoothness along the temporal direction.

23. The method of claim 22 wherein said sub-spectrograms comprise a first sub-spectrogram having smoothness along the frequency direction and a second sub-spectrogram having smoothness along the temporal direction.

24. The method of claim 23, wherein said sub-spectrogram having smoothness along the frequency direction comprises a non-harmonic component and said sub-spectrogram having smoothness along the temporal direction comprises a harmonic component.

25. The method of claim 24, wherein said acoustic signal is a music signal and said non-harmonic component relates to percussion sound.

26. The method of claim 1, said method further comprising emphasizing or suppressing the spectral elements of at least one separated sub-spectrogram.
